(19) United States
(12) Patent Application Publication
(10) Pub. No.: US 2025/0244416 A1
(43) Pub. Date: Jul. 31, 2025

(54) MAGNETIC SENSOR

(71) Applicant: TDK Corporation, Tokyo (JP)

(72) Inventors: Takashi SAITO, Tokyo (JP); Hidekazu KOJIMA, Tokyo (JP); Hirokazu TAKAHASHI, Tokyo (JP); Satoshi MIURA, Tokyo (JP)

(73) Assignee: TDK Corporation, Tokyo (JP)

(21) Appl. No.: 19/033,759

(22) Filed: Jan. 22, 2025

(30) Foreign Application Priority Data
Jan. 31, 2024 (JP) 2024-013565

(51) Int. Cl. G01R 33/09; H10N 50/10

(52) U.S. Cl. CPC G01R 33/093; H10N 50/10; G01R 33/098

(57) ABSTRACT

A magnetic sensor includes at least one MR element, a ferromagnetic layer disposed to overlap the at least one MR element when viewed in a first direction, an insulating layer disposed on both sides of the at least one MR element in a second direction, and an antiferromagnetic layer disposed on the at least one MR element, the ferromagnetic layer, and the insulating layer. The antiferromagnetic layer includes an antiferromagnetic portion that faces the ferromagnetic layer, and a non-facing part that faces the at least one MR element and the insulating layer but does not face the ferromagnetic layer. No magnetic layer is present between the at least one MR element and the antiferromagnetic layer.

### CROSS REFERENCE TO RELATED APPLICATIONS

This application claims the benefit of Japanese Priority Patent Application No. 2024-13565 filed on Jan. 31, 2024, the entire contents of which are incorporated herein by reference.

### BACKGROUND

The disclosure relates to a magnetic sensor configured to be capable of applying a bias magnetic field to a magnetoresistive element.

Magnetic sensors have been used for a variety of applications. Examples of known magnetic sensors include one that uses a spin-valve magnetoresistive element provided on a substrate. The spin-valve magnetoresistive element includes a magnetization pinned layer having a magnetization pinned in a certain direction, a free layer having a magnetization whose direction is variable depending on the direction of a target magnetic field, and a gap layer disposed between the magnetization pinned layer and the free layer.

Some magnetic sensors have means for applying a bias magnetic field to the magnetoresistive element. The bias magnetic field is used, for example, to enable the magnetoresistive element to respond linearly to a change in the strength of the target magnetic field. In a magnetic sensor that uses a spin-valve magnetoresistive element, the bias magnetic field is used also to make the free layer have a single magnetic domain and to orient the magnetization of the free layer in a certain direction when there is no target magnetic field.

As means of generating a bias magnetic field, a magnetic field generator formed by stacking an antiferromagnetic layer and a ferromagnetic layer is known. Japanese Patent Application Laid-Open Publication No. 2015-125020 and Japanese Patent Application Laid-Open Publication No. 2016-176911 disclose a magnetic sensor including a magnetoresistive element and two magnetic field generators disposed with the magnetoresistive element interposed therebetween.

In order to increase the strength of the bias magnetic field to be applied to the magnetoresistive element, it is desirable to reduce the distance between the magnetoresistive element and the magnetic field generator, and to increase the size of the magnetic field generator. For example, one option to increase the strength of the bias magnetic field to be applied to the magnetoresistive element is by forming an insulating layer around the entire magnetoresistive element and then forming a magnetic field generator on the magnetoresistive element and the insulating layer so as to cover the entire magnetoresistive element. However, doing so would cause the magnetic layer included in the magnetic field generator to function as a shield, causing a reduction in the sensitivity of the magnetoresistive element.

### SUMMARY

A magnetic sensor according to one embodiment of the disclosure includes: at least one magnetoresistive element including a plurality of magnetic films stacked on each other; a first ferromagnetic layer made of a ferromagnetic material, the first ferromagnetic layer being disposed to overlap the at least one magnetoresistive element when viewed in a first direction orthogonal to a stacking direction of the plurality of magnetic films; an insulating layer made of an insulating material, the insulating layer being disposed on both sides of the at least one magnetoresistive element in a second direction orthogonal to each of the stacking direction and the first direction; and an antiferromagnetic layer disposed on the at least one magnetoresistive element, the first ferromagnetic layer, and the insulating layer. The antiferromagnetic layer includes a first antiferromagnetic portion that faces the first ferromagnetic layer, and a non-facing part that faces the at least one magnetoresistive element and the insulating layer but does not face the first ferromagnetic layer. No magnetic layer is present between the at least one magnetoresistive element and the antiferromagnetic layer.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device including a magnetic sensor according to a first example embodiment of the disclosure.

FIG. 2 is a functional block diagram showing a configuration of the magnetic sensor device in the first example embodiment of the disclosure.

FIG. 3 is a circuit diagram showing a circuit configuration of the magnetic sensor according to the first example embodiment of the disclosure.

FIG. 4 is a perspective view showing a part of a first detection circuit in the first example embodiment of the disclosure.

FIG. 5 is a plan view showing a part of the first detection circuit in the first example embodiment of the disclosure.

FIG. 6 is a plan view showing a part of a second detection circuit in the first example embodiment of the disclosure.

FIG. 7 is a plan view showing a main part of the magnetic sensor according to the first example embodiment of the disclosure.

FIG. 8 is a plan view showing a magnetoresistive element, a magnetic field generator, and an insulating layer in the first example embodiment of the disclosure.

FIG. 9 is a cross-sectional view showing a part of a cross section at a position indicated by a 9-9 line in FIG. 7.

FIG. 10 is a cross-sectional view showing a part of a cross section at a position indicated by a 10-10 line in FIG. 7.

FIG. 11 is a cross-sectional view showing a method of forming a magnetic field generator of a comparative example.

FIGS. 12A and 12B are each a cross-sectional view showing a method of forming the magnetic field generator in the first example embodiment of the disclosure.

FIG. 13 is a plan view showing a main part of a first modification example of the magnetic sensor according to the first example embodiment of the disclosure.

FIG. 14 is a plan view showing a main part of a second modification example of the magnetic sensor according to the first example embodiment of the disclosure.

FIG. 15 is a plan view showing a main part of a third modification example of the magnetic sensor according to the first example embodiment of the disclosure.

FIG. 16 is a cross-sectional view showing a main part of a fourth modification example of the magnetic sensor according to the first example embodiment of the disclosure.

FIG. 17 is a cross-sectional view showing a main part of a fifth modification example of the magnetic sensor according to the first example embodiment of the disclosure.

FIG. 18 is a cross-sectional view showing a main part of a sixth modification example of the magnetic sensor according to the first example embodiment of the disclosure.

FIG. 19 is a cross-sectional view showing a main part of a seventh modification example of the magnetic sensor according to the first example embodiment of the disclosure.

FIG. 20 is a perspective view showing a magnetic sensor system including a magnetic sensor according to a second example embodiment of the disclosure.

FIG. 21 is a circuit diagram showing a circuit configuration of the magnetic sensor according to the second example embodiment of the disclosure.

FIG. 22 is a perspective view showing a part of the magnetic sensor according to the second example embodiment of the disclosure.

FIG. 23 is a plan view showing a part of the magnetic sensor according to the second example embodiment of the disclosure.

FIG. 24 is a side view showing a part of the magnetic sensor according to the second example embodiment of the disclosure.

FIG. 25 is a plan view showing a main part of the magnetic sensor according to the second example embodiment of the disclosure.

FIG. 26 is a cross-sectional view showing a part of a cross section at a position indicated by a 26-26 line in FIG. 25.

FIG. 27 is a cross-sectional view showing a part of a cross section at a position indicated by a 27-27 line in FIG. 25.

FIG. 28 is a plan view showing a main part of a magnetic sensor according to a third example embodiment of the disclosure.

FIG. 29 is a cross-sectional view showing a part of a cross section at a position indicated by a 29-29 line in FIG. 28.

FIG. 30 is a cross-sectional view showing a part of a cross section at a position indicated by a 30-30 line in FIG. 28.

### DETAILED DESCRIPTION

It is an object of the disclosure to provide a magnetic sensor capable of restraining a reduction in the sensitivity of a magnetoresistive element.

In the following, some example embodiments and modification examples of the disclosure are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

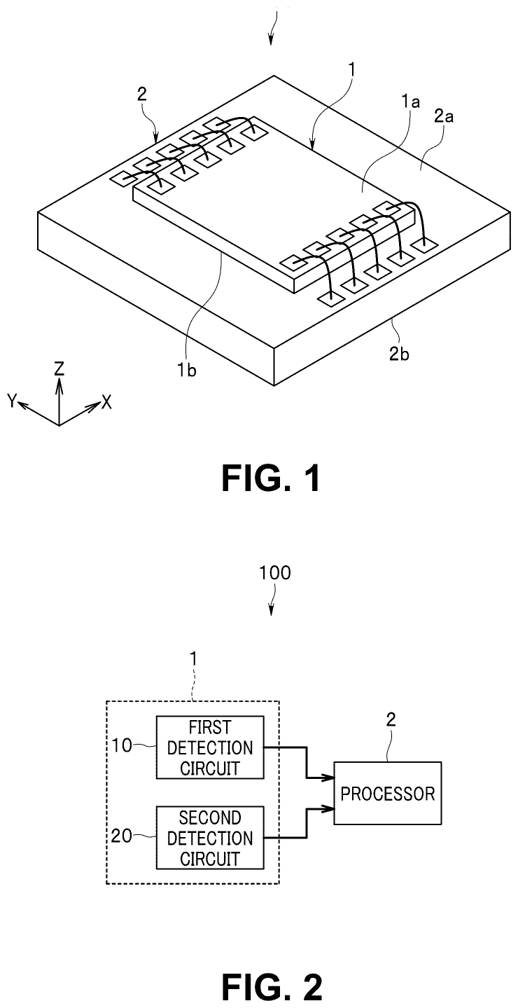

Initially, a configuration of a magnetic sensor device including a magnetic sensor according to a first example embodiment of the disclosure is described with reference to FIGS. 1 and 2. FIG. 1 is a perspective view showing the magnetic sensor device in the example embodiment. FIG. 2 is a functional block diagram showing a configuration of the magnetic sensor device in the example embodiment.

A magnetic sensor device 100 in the example embodiment includes a magnetic sensor 1 according to the example embodiment and a processor 2. The magnetic sensor 1 is configured to detect a target magnetic field, which is a magnetic field to be detected by the magnetic sensor 1, and to generate at least one detection signal. The magnetic sensor 1 may be a geomagnetic sensor that detects a geomagnetic field, a magnetic sensor for angle sensors or magnetic encoders that detects a rotating magnetic field, or a magnetic sensor for current sensors that detects a magnetic field generated by a current to be detected.

The processor 2 is configured to generate at least one detection value having a correspondence with the target magnetic field, based on at least one detection signal. The processor 2 is constituted, for example, by an application-specific integrated circuit (ASIC).

Each of the magnetic sensor 1 and the processor 2 is in a form of a chip having a rectangular parallelepiped shape. The magnetic sensor 1 includes a top surface 1a and a bottom surface 1b located on opposite sides of each other, and four side surfaces connecting the top surface 1a and the bottom surface 1b. The processor 2 includes a top surface 2a and a bottom surface 2b located on opposite sides of each other and four side surfaces connecting the top surface 2a and the bottom surface 2b. The magnetic sensor 1 is mounted on the top surface 2a of the processor 2 in such an orientation that the bottom surface 1b of the magnetic sensor 1 faces the top surface 2a of the processor 2. The magnetic sensor 1 is bonded to the processor 2 by an adhesive, for example.

Here, X, Y, and Z directions are defined as shown in FIG. 1. The X, Y, and Z directions are orthogonal to one another. In the example embodiment, the Z direction is a direction perpendicular to the top surface 1a of the magnetic sensor 1 and from the bottom surface 1b to the top surface 1a of the magnetic sensor 1. The directions opposite to the X, Y, and Z directions will be referred to as −X, −Y, and −Z directions, respectively.

Hereafter, the term “above” refers to positions located forward of a reference position in the Z direction, and “below” refers to positions located on a side of the reference position opposite from “above”. With respect to components of the magnetic sensor 1, the surface located at the end in the Z direction is referred to as “top surface,” and the surface located at the end of the −Z direction is referred to as “bottom surface. The expression “when viewed in a predetermined direction (e.g., the Z direction)” means that an object is viewed in a position away in the predetermined direction or in one direction parallel to the predetermined direction.

The magnetic sensor 1 includes a plurality of first pads (electrode pads) provided on the top surface 1a. The processor 2 includes a plurality of second pads (electrode pads) provided on the top surface 2a. In the magnetic sensor 1, of the plurality of first pads and the plurality of second pads, two corresponding pads are connected to each other by a bonding wire.

The magnetic sensor 1 includes a first detection circuit 10 and a second detection circuit 20. The first and second detection circuits 10 and 20 and the processor 2 are connected via a plurality of first pads, a plurality of second pads, and a plurality of bonding wires.

Each of the first and second detection circuits 10 and 20 includes a plurality of magnetic detection elements. In the example embodiment in particular, the plurality of magnetic detection elements are a plurality of magnetoresistive elements. Magnetoresistive elements will hereinafter be referred to as MR elements.

The first detection circuit 10 detects a component in a direction parallel to the X direction of the target magnetic field and generates at least one first detection signal having a correspondence with this component. The second detection circuit 20 detects a component in a direction parallel to the Y direction of the target magnetic field and generates at least one second detection signal having a correspondence with this component.

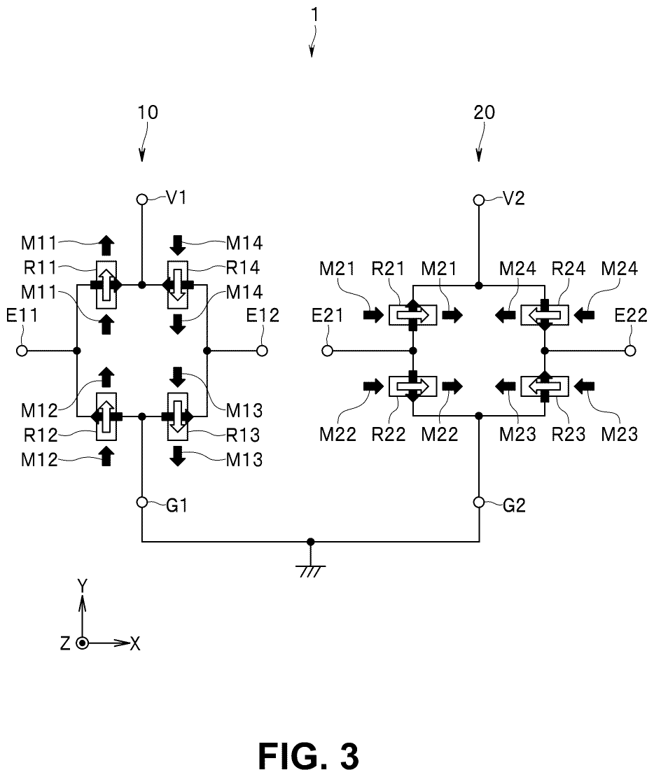

Next, a circuit configuration of the magnetic sensor 1 is described with reference to FIG. 3. FIG. 3 is a circuit diagram showing the circuit configuration of the magnetic sensor 1.

The first detection circuit 10 includes four resistor sections R11, R12, R13, and R14, a power supply port V1, a ground port G1, and two output ports E11 and E12. The resistor section R11 is provided between the power supply port V1 and the output port E11. The resistor section R12 is provided between the output port E11 and the ground port G1. The resistor section R13 is provided between the output port E12 and the ground port G1. The resistor section R14 is provided between the power supply port V1 and the output port E12. A voltage or current of a predetermined magnitude is applied to the power supply port V1. The ground port G1 is connected to ground.

The second detection circuit 20 includes four resistor sections R21, R22, R23, and R24, a power supply port V2, a ground port G2, and two output ports E21 and E22. The resistor section R21 is provided between the power supply port V2 and the output port E21. The resistor section R22 is provided between the output port E21 and the ground port G2. The resistor section R23 is provided between the output port E22 and the ground port G2. The resistor section R24 is provided between the power supply port V2 and the output port E22. A voltage or current of a predetermined magnitude is applied to the power supply port V2. The ground port G2 is connected to ground.

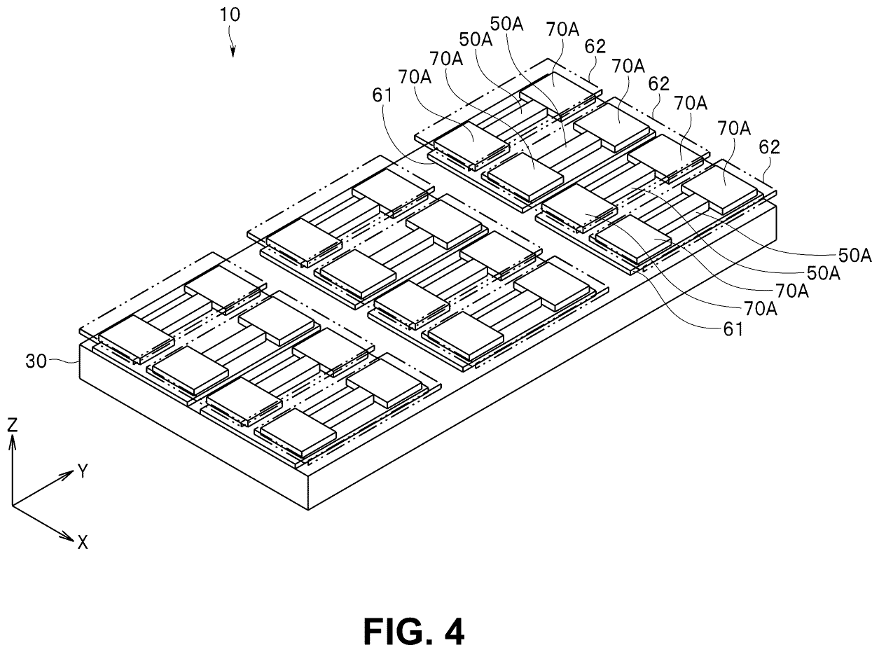

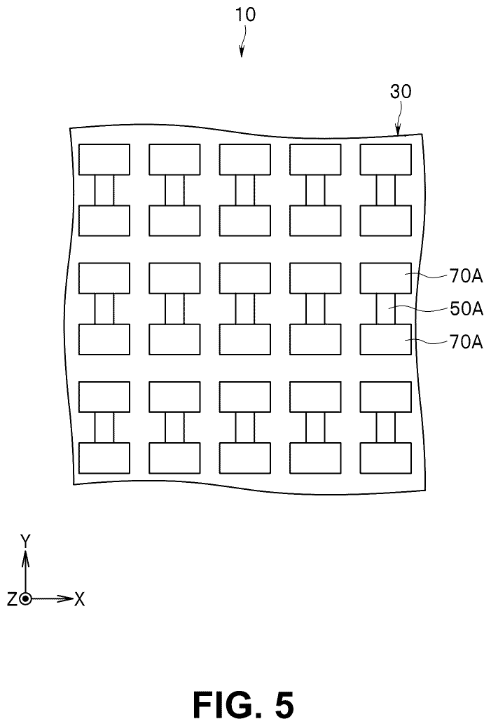

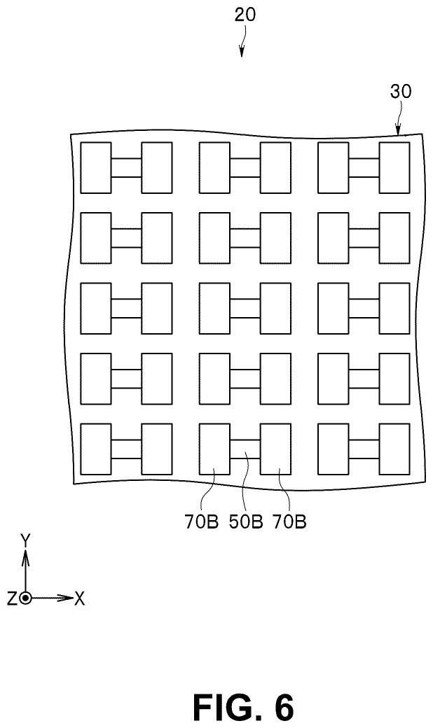

Next, respective configurations of the first and second detection circuits 10 and 20 are described with reference to FIGS. 4 through 6. FIG. 4 is a perspective view showing a part of the first detection circuit 10. FIG. 5 is a plan view showing a part of the first detection circuit 10. FIG. 6 is a plan view showing a part of the second detection circuit 20.

The magnetic sensor 1 further includes a substrate 30. The magnetic sensor 1 is constituted by forming, on the substrate 30, a plurality of components other than the substrate 30. The first detection circuit 10 and the second detection circuit 20 are provided on the substrate 30. Each of the resistor sections R11 to R14 includes a plurality of MR elements 50A. Each of the resistor sections R21 to R24 includes a plurality of MR elements 50B.

Each of the resistor sections R11 to R14 further includes a plurality of lower electrodes 61 and a plurality of upper electrodes 62. As shown in FIGS. 4 and 5, each of the plurality of MR elements 50A has a shape long in a direction parallel to the Y direction. Each of the plurality of lower electrodes 61 electrically connects two adjacent MR elements 50A in a direction parallel to the X direction. Each of the plurality of upper electrodes 62 electrically connect the two adjacent MR elements 50A disposed on two lower electrodes 61. The plurality of MR elements 50A arranged in a row in a direction parallel to the X direction are thereby connected in series.

Each of the resistor sections R11 to R14 further includes a plurality of connecting electrodes (not shown). In each of the resistor sections R11 to R14, the plurality of connecting electrodes electrically connect the plurality of lower electrodes 61 or the plurality of upper electrodes 62 so that a group of the plurality of MR elements 50A arranged in a row is connected in series. With such a configuration, each of the resistor sections R11 to R14 includes the plurality of MR elements 50A connected in series by the plurality of lower electrodes 61, the plurality of upper electrodes 62, and the plurality of connecting electrodes.

The above description of the connection relationship of the plurality of MR elements 50A is basically applicable also to the plurality of MR elements 50B of each of the resistor sections R21 to R24. As shown in FIG. 6, in each of the resistor sections R21 to R24, each of the plurality of MR elements 50B has a shape long in a direction parallel to the X direction. In the above description of the connection relationship of the plurality of MR elements 50A, if the plurality of MR elements 50A, the X direction, and the Y direction are replaced with the plurality of MR elements 50B, the Y direction, and the X direction, respectively, a connection relationship of the plurality of MR elements 50B is described.

Each of the resistor sections R11 to R14 further includes a plurality of magnetic field generators 70A. The plurality of magnetic field generators 70A include a plurality of pairs of the magnetic field generators 70A, each pair including two magnetic field generators 70A. The two magnetic field generators 70A are disposed at a distance from each other in a direction parallel to the Y direction with one MR element 50A interposed therebetween. The two magnetic field generators 70A are configured to apply a bias magnetic field to the one MR element 50A located therebetween. This bias magnetic field includes, as the main component, a component in a direction parallel to the Y direction.

Each of the resistor sections R21 to R24 further includes a plurality of magnetic field generators 70B. The plurality of magnetic field generators 70B include a plurality of pairs of the magnetic field generators 70B, each pair including two magnetic field generators 70B. The two magnetic field generators 70B are disposed at a distance from each other in a direction parallel to the X direction with one MR element 50B interposed therebetween. The two magnetic field generators 70B are configured to apply a bias magnetic field to the one MR element 50B located therebetween. This bias magnetic field includes, as the main component, a component parallel to the X direction.

As shown in FIG. 4, each of the plurality of magnetic field generators 70A may be interposed between the lower electrode 61 and the upper electrode 62. Although not shown, each of the plurality of magnetic field generators 70B may be interposed between the lower electrode 61 and the upper electrode 62.

In the example embodiment, each of the plurality of MR elements 50A and the plurality of MR elements 50B is a spin-valve MR element. The spin-valve MR element includes a magnetization pinned layer having a magnetization pinned in a certain direction, a free layer having a magnetization whose direction is variable depending on the direction of a target magnetic field, and a gap layer disposed between the magnetization pinned layer and the free layer. The spin-valve MR element may be a TMR (tunneling magnetoresistive) element or may be a GMR (giant magnetoresistive) element. In the TMR element, the gap layer is a tunnel barrier layer. In the GMR element, the gap layer is a nonmagnetic conductive layer. The spin-valve MR element changes in resistance value depending on an angle that the magnetization direction of the free layer forms with respect to the magnetization direction of the magnetization pinned layer, and the resistance value is a minimum value when the angle is 0° and the resistance value is a maximum value when the angle is 180°. In each MR element, the free layer has shape anisotropy in which the direction of the magnetization easy axis is orthogonal to the magnetization direction of the magnetization pinned layer.

The spin-valve MR element may further include an antiferromagnetic layer. The antiferromagnetic layer is made of antiferromagnetic material, and generate exchange coupling with the magnetization pinned layer to fix the magnetization direction of the magnetization pinned layer. The magnetization pinned layer may be a so-called self-pinned layer (Synthetic Ferri Pinned layer, SFP layer). The self-pinned layer has a stacked ferri-structure in which a ferromagnetic layer, a nonmagnetic intermediate layer, and a ferromagnetic layer are stacked on each other, and is formed by antiferromagnetically coupling the two ferromagnetic layers. If the magnetization pinned layer is a self-pinned layer, the antiferromagnetic layer may be omitted.

Next, the magnetization direction of the magnetization pinned layer and the direction of the bias magnetic field are described with reference to FIG. 3. In FIG. 3, a plurality of solid arrows drawn to overlap the resistor sections R11 to R14 and R21 to R24, respectively, represent the magnetization direction of the magnetization pinned layer in each of the resistor sections R11 to R14 and R21 to R24. In the example shown in FIG. 3, the direction of the main component of the magnetization of the magnetization pinned layer in each of the resistor sections R11 and R13 is the X direction. The direction of the main component of the magnetization of the magnetization pinned layer in each of the resistor sections R12 and R14 is the −X direction. The free layer in each of the resistor sections R11 to R14 has shape anisotropy in which the direction of the magnetization easy axis is a direction parallel to the Y direction.

The direction of the main component of the magnetization of the magnetization pinned layer in each of the resistor sections R21 and R23 is the Y direction. The direction of the main component of the magnetization of the magnetization pinned layer in each of the resistor sections R22 and R24 is the −Y direction. The free layer in each of the resistor sections R21 to R24 has shape anisotropy in which the direction of the magnetization easy axis is a direction parallel to the X direction.

In FIG. 3, arrows labelled with the reference numerals M11, M12, M13, and M14 indicate the directions of the main components of the bias magnetic fields generated by the plurality of magnetic field generators 70A of the resistor sections R11, R12, R13, and R14, respectively. The direction of the main component of the bias magnetic field at the resistor sections R11 and R12 is the Y direction. The direction of the main component of the bias magnetic field at the resistor sections R13 and R14 is the −Y direction.

In FIG. 3, the plurality of hollow arrows drawn to overlap the resistor sections R11 to R14, respectively, represent the magnetization direction of the free layer in each of the resistor sections R11 to R14 in a case where the target magnetic field is not applied to the magnetic sensor 1. The direction of the main component of the magnetization of the free layer in each of the resistor sections R11 and R12 is the Y direction, and is the same as the direction of the main component of the bias magnetic field at the resistor sections R11 and R12. The direction of the main component of the magnetization of the free layer in each of the resistor sections R13 and R14 is the −Y direction, and is the same as the direction of the main component of the bias magnetic field at the resistor sections R13 and R14.

In FIG. 3, arrows labelled with the reference numerals M21, M22, M23, and M24 indicate the directions of the main components of the bias magnetic fields generated by the plurality of magnetic field generators 70B in the resistor sections R21, R22, R23, and R24, respectively. The direction of the main component of the bias magnetic field at the resistor sections R21 and R22 is the X direction. The direction of the main component of the bias magnetic field at the resistor sections R23 and R24 is the −X direction.

In FIG. 3, the plurality of hollow arrows drawn to overlap the resistor sections R21 to R24, respectively, represent the magnetization direction of the free layer in each of the resistor sections R21 to R24 in a case where the target magnetic field is not applied to the magnetic sensor 1. The direction of the main component of the magnetization of the free layer in each of the resistor sections R21 and R22 is the X direction, and is the same as the direction of the main component of the bias magnetic field at the resistor sections R21 and R22. The direction of the main component of the magnetization of the free layer in each of the resistor sections R23 and R24 is the −X direction, and is the same as the direction of the main component of the bias magnetic field at the resistor sections R23 and R24.

Note that the magnetization direction may coincide with the direction of the main component of the magnetization mentioned above, or may deviate slightly from the direction of the main component of the magnetization. Similarly, the direction of the bias magnetic field may coincide with the direction of the main component of the bias magnetic field mentioned above, or may deviate slightly from the direction of the main component of the bias magnetic field. In the following description, the magnetization direction is assumed to coincide with the direction of the main component of the magnetization, and the direction of the bias magnetic field is assumed to coincide with the direction of the main component of the bias magnetic field.

Next, operations of the first and second detection circuits 10 and 20 are described with reference to FIG. 3. In the first detection circuit 10, the potential of the connection point between the resistor sections R11 and R12, i.e., the potential of the output port E11, and the potential of the connection point between the resistor sections R13 and R14, i.e., the potential of the output port E12, change depending on the strength of the component in a direction parallel to the X direction of the target magnetic field. The first detection circuit 10 may generate a signal corresponding to the potential of the output port E11 and a signal corresponding to the potential of the output port E12, each as a first detection signal. Alternatively, the first detection circuit 10 may generate a signal corresponding to the potential difference between the output ports E11 and E12 as the first detection signal. In this case, the first detection circuit 10 may further include a differential amplifier (difference detector) that outputs the signal corresponding to the potential difference between the output ports E11 and E12 as the first detection signal.

In the second detection circuit 20, the potential of the connection point between the resistor sections R21 and R22, i.e., the potential of the output port E21, and the potential of the connection point between the resistor sections R23 and R24, i.e., the potential of the output port E22, change depending on the strength of the component in a direction parallel to the Y direction of the target magnetic field. The second detection circuit 20 may generate a signal corresponding to the potential of the output port E21 and a signal corresponding to the potential of the output port E22, each as a second detection signal. Alternatively, the second detection circuit 20 may generate a signal corresponding to the potential difference between the output ports E21 and E22 as the second detection signal. In this case, the second detection circuit 20 may further include a differential amplifier (difference detector) that outputs the signal corresponding to the potential difference between the output ports E21 and E22 as the second detection signal.

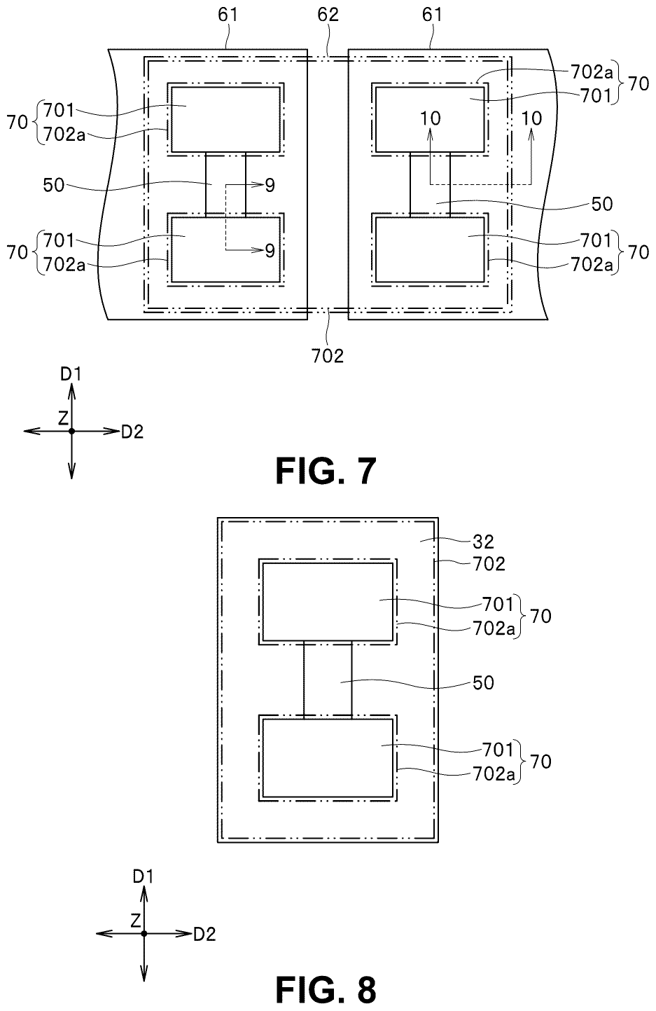

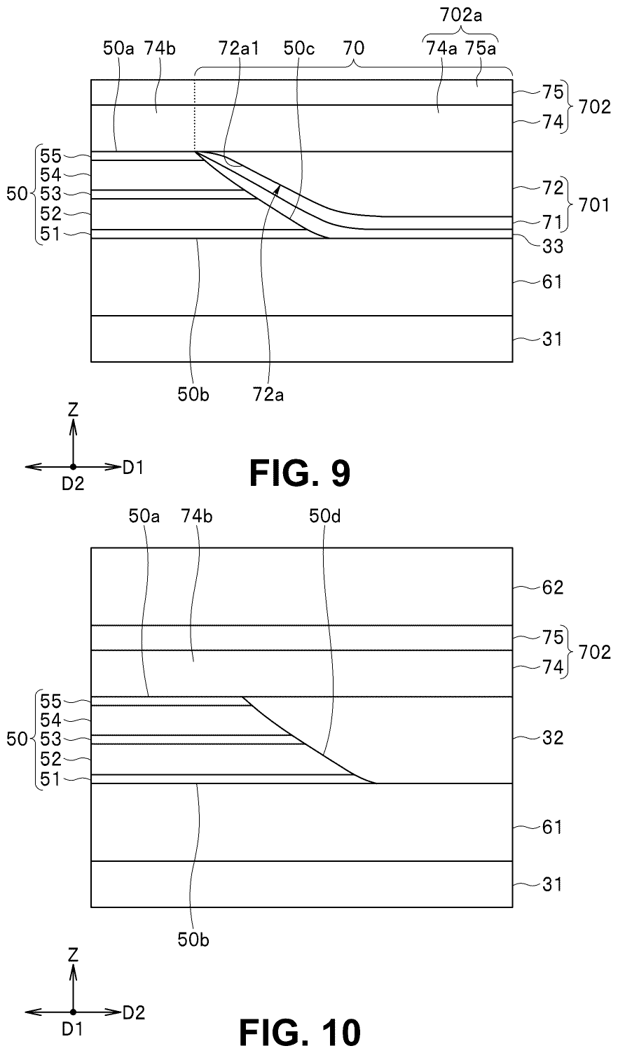

Next, configurations of the plurality of MR elements 50A, the plurality of MR elements 50B, the plurality of magnetic field generators 70A, and the plurality of magnetic field generators 70B are described in detail with reference to FIGS. 7 through 10. FIG. 7 is a plan view showing a main part of the magnetic sensor 1. FIG. 8 is a plan view showing the MR element, the magnetic field generators, and an insulating layer. FIG. 9 is a cross-sectional view showing a part of a cross section at a position indicated by a 9-9 line in FIG. 7. FIG. 10 is a cross-sectional view showing a part of a cross section at a position indicated by a 10-10 line in FIG. 7.

Here, a first direction D1 and a second direction D2, which are each orthogonal to the Z direction and are orthogonal to each other, are defined as shown in FIGS. 7 through 10. In the first detection circuit 10, the first direction D1 is a direction parallel to the Y direction and the second direction D2 is a direction parallel to the X direction. In the second detection circuit 20, the first direction D1 is a direction parallel to the X direction and the second direction D2 is a direction parallel to the Y direction.

Hereinafter, any MR element of the plurality of MR elements 50A and the plurality of MR elements 50B will be denoted using the reference numeral 50, and any magnetic field generator of the plurality of magnetic field generators 70A and the plurality of magnetic field generators 70B will be denoted using the reference numeral 70. The magnetic sensor 1 includes at least one MR element 50. In the example embodiment in particular, the magnetic sensor 1 includes a plurality of MR elements 50 as the at least one MR element 50.

Here, configurations of the MR element 50 and the magnetic field generator 70 are described with a focus on one MR element 50. The MR element 50 includes a plurality of magnetic films. The stacking direction of the plurality of magnetic films is a direction parallel to the Z direction. The plurality of magnetic films include a magnetization pinned layer 52 and a free layer 54. Each of the plurality of MR elements 50 further includes a gap layer 53, a buffer layer 51, and a cap layer 55. As shown in FIGS. 9 and 10, the buffer layer 51, the magnetization pinned layer 52, the gap layer 53, the free layer 54, and the cap layer 55 are stacked in this order in the Z direction. Each of the buffer layer 51 and the cap layer 55 is formed of a nonmagnetic metallic material such as, for example, Ru, Ta, Cu, or Cr.

The MR element 50 includes a top surface 50a located at the end in the Z direction, a bottom surface 50b located at the end in the −Z direction, two side surfaces 50c located at both ends in the first direction D1, and two side surfaces 50d located at both ends in the second direction D2. The bottom surface 50b of the MR element 50 is in contact with the lower electrode 61. Each of the two side surfaces 50c and the two side surfaces 50d is inclined with respect to the stacking direction (direction parallel to the Z direction) of the plurality of magnetic films.

The magnetic sensor 1 further includes at least one ferromagnetic layer 72 made of a ferromagnetic material and an insulating layer 32 made of an insulating material such as Al₂O₃ or SiO₂. The at least one ferromagnetic layer 72 is disposed to overlap the MR element 50 when viewed in the first direction D1. In the example embodiment in particular, the at least one ferromagnetic layer 72 is disposed to overlap the entirety of the free layer 54 when viewed in the first direction D1.

The at least one ferromagnetic layer 72 is disposed to ride up on a side surface 50c of the MR element 50. A part of the at least one ferromagnetic layer 72 overlaps a part of the MR element 50 when viewed in the Z direction. The insulating layer 32 is disposed on both sides of the MR element 50 in the second direction D2.

In the example embodiment in particular, the MR element 50 is disposed between two ferromagnetic layers 72 disposed at a distance from each other in the first direction D1. The insulating layer 32 is disposed around the MR element 50 and the two ferromagnetic layers 72.

The ferromagnetic layer 72 is formed of a ferromagnetic material containing one or more elements selected from the group consisting of Co, Fe and Ni. Examples of such a ferromagnetic material include CoFe, CoFeB, and CoNiFe. The ferromagnetic layer 72 may be formed of a stack of two or more layers in which every adjacent two layers are formed of different ferromagnetic materials. Examples of such a stack forming the ferromagnetic layer 72 include a stack of a Co layer, a CoFe layer, and a Co layer, and a stack of a Co₇₀Fe₃₀ layer, a Co₃₀Fe₇₀ layer, and a Co₇₀Fe₃₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fc.

The magnetic sensor 1 further includes two buffer layers 71 respectively disposed on the bottom surface side (−Z direction side) of a plurality of the two ferromagnetic layers 72. The two buffer layers 71 are formed of a nonmagnetic metallic material such as, for example, Ru, Ta, Cu, or Cr.

The magnetic sensor 1 further includes an antiferromagnetic layer 74 disposed on the MR element 50, the two ferromagnetic layers 72, and the insulating layer 32, and a cap layer 75 disposed on the antiferromagnetic layer 74. The antiferromagnetic layer 74 includes two antiferromagnetic portions 74a that face the two ferromagnetic layers 72, and a non-facing part 74b that faces the MR element 50 and the insulating layer 32 but does not face the two ferromagnetic layers 72. The two antiferromagnetic portions 74a are connected to each other by the non-facing part 74b. No magnetic layer is present between the MR element 50 and the antiferromagnetic layer 74. The cap layer 75 includes two protective portions 75a disposed on the two antiferromagnetic portions 74a.

The antiferromagnetic layer 74 is formed of an antiferromagnetic material such as, for example, IrMn or PtMn. The cap layer 75 is formed of a nonmagnetic metallic material such as, for example, Ru, Ta, Cu, or Cr.

The buffer layer 71 and the ferromagnetic layer 72 constitute a first stack 701. The antiferromagnetic layer 74 and the cap layer 75 constitute a second stack 702. The MR element 50 is disposed between two first stacks 701. The second stack 702 is disposed on the MR element 50, the insulating layer 32, and the two first stacks 701.

The second stack 702 includes two stacked parts 702a disposed on the two first stacks 701. Each of the two stacked parts 702a includes an antiferromagnetic portion 74a and a protective portion 75a.

The ferromagnetic layer 72 has an overall magnetization. The overall magnetization of the ferromagnetic layer 72 is a volume average of the vector sum of magnetic moments for each unit of atoms, crystal lattices, etc., in the overall ferromagnetic layer 72. Hereinafter, the overall magnetization of the ferromagnetic layer 72 is simply referred to as magnetization of the ferromagnetic layer 72. In a stack including the first stack 701 and a stacked part 702a disposed on the first stack 701, the antiferromagnetic portion 74a is in contact with the top surface of the ferromagnetic layer 72 to be exchange-coupled with the ferromagnetic layer 72. This defines the magnetization direction of the ferromagnetic layer 72. The ferromagnetic layer 72 and the antiferromagnetic portion 74a may constitute the magnetic field generator 70 that generates a bias magnetic field to be applied to the MR element 50 based on the magnetization of the ferromagnetic layer 72. The magnetic field generator 70 thus constituted is highly resistant to disturbance magnetic fields.

Since the ferromagnetic layer 72 is a part of the first stack 701 and the antiferromagnetic portion 74a is a part of the stacked part 702a, it can be said that the first stack 701 and the stacked part 702a constitute the magnetic field generator 70. The magnetic field generator 70 includes the buffer layer 71, the ferromagnetic layer 72, the antiferromagnetic portion 74a, and the protective portion 75a. The MR element 50 is disposed between two magnetic field generators 70. The two magnetic field generators 70 cooperate to apply a bias magnetic field to the MR element 50. The magnetization direction of the ferromagnetic layer 72 of one of the two magnetic field generators 70 may be the same as the magnetization direction of the ferromagnetic layer 72 of the other of the two magnetic field generators 70. In this case, the direction of the bias magnetic field generated by one of the two magnetic field generators 70 becomes the same as the direction of the bias magnetic field generated by the other of the two magnetic field generators 70.

The top surface 50a of the MR element 50 faces the non-facing part 74b of the antiferromagnetic layer 74. The distance between at least a part of the non-facing part 74b and the bottom surface 50b of the MR element 50 may be the same as the distance between the top surface 50a and the bottom surface 50b. The distance between the antiferromagnetic portion 74a of the antiferromagnetic layer 74 and the top surface of the lower electrode 61 may be the same as the distance between the non-facing part 74b and the bottom surface 50b, or may be different from the distance between the non-facing part 74b and the bottom surface 50b. In the latter case, the maximum distance between the antiferromagnetic portion 74a and the top surface of the lower electrode 61 may be larger or may be smaller than the distance between the non-facing part 74b and the bottom surface 50b.

The ferromagnetic layer 72 has a side surface 72a facing the side surface 50c of the MR element 50. The side surface 72a includes an inclined part 72al facing the free layer 54 of the MR element 50 and inclined with respect to the stacking direction (a direction parallel to the Z direction) of the plurality of magnetic films. The angle that the inclined part 72al forms with respect to the stacking direction is within a range equal to or larger than 20° and equal to or smaller than 90°.

The magnetic sensor 1 further includes an insulating layer 31 made of an insulating material and interposed between the substrate 30 (see FIGS. 4 through 6) and the lower electrode 61, and an insulating layer 33 made of an insulating material and interposed between the MR element 50 and the two first stacks 701. The insulating layers 31 and 33 are formed of an insulating material such as, for example, Al₂O₃ or SiO₂.

The top surface of the second stack 702, i.e., the top surface of the cap layer 75, is in contact with the upper electrode 62. The planar shape of the second stack 702 (shape viewed in the Z direction) may coincide with, may be smaller than, or may be larger than the planar shape of the upper electrode 62. The magnetic sensor 1 further includes an insulating layer (not shown) made of an insulating material and disposed on the upper electrode 62.

Heretofore, the configurations of the MR element 50 and the magnetic field generator 70 have been described with a focus on one MR element 50. In the example embodiment, the magnetic sensor 1 includes the plurality of MR elements 50. As shown in FIG. 7, the plurality of MR elements 50 include two MR elements 50 arranged along the second direction D2. The second stack 702 is interposed between the two MR elements 50 and the upper electrode 62 electrically connecting the two MR elements 50. In the example shown in FIG. 7, the second stack 702 is disposed on the two MR elements 50 and four first stacks 701. In this example, the second stack 702 includes four stacked parts 702a.

The two MR elements 50 are electrically connected also by the antiferromagnetic layer 74 of the second stack 702. The two MR elements 50 may be connected in series by the antiferromagnetic layer 74.

In the example embodiment, since the magnetic sensor 1 includes the plurality of MR elements 50 and a plurality of magnetic field generators 70, the magnetic sensor 1 includes a plurality of buffer layers 71, a plurality of ferromagnetic layers 72, a plurality of antiferromagnetic layers 74, and a plurality of cap layers 75.

Next, an operation and effect of the magnetic sensor 1 according to the example embodiment are described. In the example embodiment, the antiferromagnetic layer 74 is disposed on the MR element 50, the two ferromagnetic layers 72, and the insulating layer 32. No magnetic layer is present between the MR element 50 and the antiferromagnetic layer 74. According to the example embodiment, this enables to restrain the reduction in the sensitivity of the MR element 50.

In the example embodiment, the antiferromagnetic layer 74 includes the antiferromagnetic portion 74a that is exchange-coupled with the ferromagnetic layer 72 to define the magnetization direction of the ferromagnetic layer 72. As described below, in the example embodiment, the underlying part on which the antiferromagnetic layer 74 is formed is flat or nearly flat, and the antiferromagnetic layer 74 can be formed in a state where no structures are provided on the underlying part. According to the example embodiment, this enables to restrain the film thickness of the antiferromagnetic portion 74a from becoming small. According to the example embodiment, this enables to effectively use the antiferromagnetic portion 74a, and as a result, the above-described function of the antiferromagnetic portion 74a and the function of the magnetic field generator 70 can be realized.

In the example embodiment, the cap layer 75 is formed on the antiferromagnetic layer 74. The cap layer 75 includes the protective portion 75a that protects the antiferromagnetic portion 74a. According to the example embodiment, by forming the cap layer 75 on the antiferromagnetic layer 74, it is enabled to restrain the film thickness of the protective portion 75a from becoming small. According to the example embodiment, this enables to effectively use the protective portion 75a, and as a result, the above-described function of the protective portion 75a can be realized.

The following describes in detail the above-described effect in comparison with a magnetic sensor of a comparative example including a magnetic field generator of the comparative example. Initially, a configuration of the magnetic sensor of the comparative example is described. The magnetic sensor of the comparative example includes a magnetic field generator 170 of the comparative example instead of the magnetic field generator 70 in the example embodiment.

The magnetic field generator 170 includes a buffer layer 171, a ferromagnetic layer 172, an antiferromagnetic layer 173, and a cap layer 174. The buffer layer 171, the ferromagnetic layer 172, the antiferromagnetic layer 173, and the cap layer 174 correspond respectively to the buffer layer 71, the ferromagnetic layer 72, the antiferromagnetic layer 74, and the cap layer 75 in the example embodiment. In the comparative example, the antiferromagnetic layer 173 is in contact with the top surface of the ferromagnetic layer 172 to be exchange-coupled with the ferromagnetic layer 172. This defines the magnetization direction of the ferromagnetic layer 172.

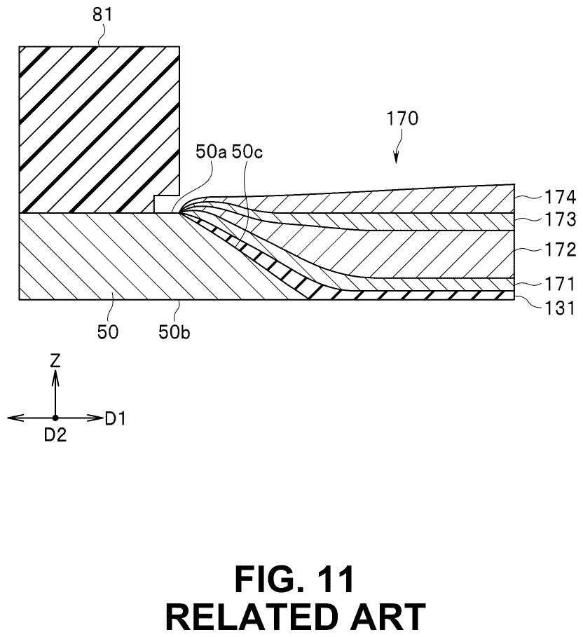

FIG. 11 is a cross-sectional view showing a method of forming the magnetic field generator of the comparative example. The magnetic field generator 170 of the comparative example is formed as follows. First, a stacked film that later becomes the MR element 50 is patterned to form the two side surfaces 50d (see FIG. 10) on this stacked film. Next, the insulating layer 32 (see FIGS. 8 and 10) is formed around the stacked film.

Next, a photoresist mask 81 is formed on the stacked film as shown in FIG. 11. Next, the photoresist mask 81 is used to pattern the stacked film by etching so that the two side surfaces 50c are formed on the stacked film. This causes the stacked film to become the MR element 50.

Next, while leaving the photoresist mask 81 in place, the insulating layer 131, the buffer layer 171, the ferromagnetic layer 172, the antiferromagnetic layer 173, and the cap layer 174 are formed in order. This completes the magnetic field generator 170. Next, the photoresist mask 81 is removed. Note that the photoresist mask 81 may be formed after the MR element 50 is patterned.

As shown in FIG. 11, the film thickness of the antiferromagnetic layer 173 becomes smaller with the decreasing distance to the photoresist mask 81 due to the influence of the shadow of the photoresist mask 81. Therefore, in the vicinity of a corner at the position where the top surface 50a and the side surface 50c of the MR element 50 intersect, the blocking temperature of the antiferromagnetic layer 173 decreases and the heat resistance of the antiferromagnetic layer 173 decreases. Therefore, under an environment where the temperature is high temporarily or for a long period of time, the function of the antiferromagnetic layer 173 and the function of the magnetic field generator 170 cannot be fulfilled.

Similarly, the film thickness of the cap layer 174 becomes smaller with the decreasing distance to the photoresist mask 81 due to the influence of the shadow of the photoresist mask 81. Therefore, in the vicinity of the corner described above, the antiferromagnetic layer 173 cannot be sufficiently protected, which poses a risk of corrosion of the antiferromagnetic layer 173. If the antiferromagnetic layer 173 corrodes, the function of the antiferromagnetic layer 173 and the function of the magnetic field generator 170 cannot be fulfilled.

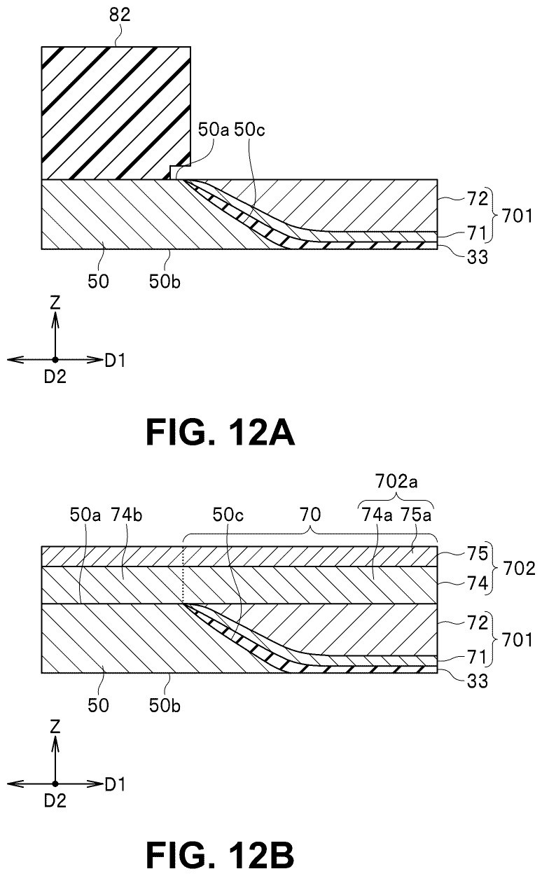

In contrast, in the example embodiment, it is enabled to restrain the film thickness of each of the antiferromagnetic portion 74a and the protective portion 75a from becoming smaller. FIGS. 12A and 12B are each a cross-sectional view showing a method of forming the magnetic field generator 70 in the example embodiment. The magnetic field generator 70 in the example embodiment is formed as follows. First, a stacked film that later becomes the MR element 50 is patterned to form the two side surfaces 50d (see FIG. 10) on the stacked film. Next, the insulating layer 32 (see FIGS. 8 and 10) is formed around the stacked film.

Next, a photoresist mask 82 is formed on the stacked film as shown in FIG. 12A. Next, the photoresist mask 82 is used to pattern the stacked film by etching so that the two side surfaces 50c are formed on the stacked film. This causes the stacked film to become the MR element 50. Next, while leaving the photoresist mask 82 in place, the insulating layer 33, the buffer layer 71, and the ferromagnetic layer 72 are formed in order.

Next, the photoresist mask 82 is removed as shown in FIG. 12B. Next, the antiferromagnetic layer 74 and the cap layer 75 are formed in order over the MR element 50, the ferromagnetic layer 72, and the insulating layer 32. Next, a process of fixing the magnetization direction of the ferromagnetic layer 72 is performed. This completes the magnetic field generator 70. A process of fixing the magnetization direction of the ferromagnetic layer 72 will be described in detail later.

As shown in FIG. 12B, in the example embodiment, the antiferromagnetic layer 74 and the cap layer 75 are formed over the stack of the MR element 50, the ferromagnetic layer 72, and the insulating layer 32. The top surface of this stack is flat or nearly flat. When forming the antiferromagnetic layer 74 and the cap layer 75, no structures such as a photoresist mask are present on the stack. Because of these factors, in the example embodiment, the film thickness of each of the antiferromagnetic layer 74 and the cap layer 75 is constant or nearly constant regardless of the distance from the MR element 50. Thus, according to the example embodiment, it is enabled to restrain the film thickness of each of the antiferromagnetic portion 74a and the protective portion 75a from becoming smaller. As a result, according to the example embodiment, it is enabled to effectively use the antiferromagnetic portion 74a and the protective portion 75a.

In the example embodiment, the insulating layer 32 has a function of restraining fluctuations in the film thickness of each of the layers formed over the MR element 50. In other words, if the insulating layer 32 were not present, a part of each of the antiferromagnetic layer 74 and the cap layer 75 would be formed along the two side surfaces 50d of the MR element 50. In this case, the film thickness of each of the layers formed along the two side surfaces 50d of the MR element 50 can be different from the film thickness of each of the layers formed along the top surface 50a of the MR element 50 and the top surface of the ferromagnetic layer 72. In contrast, according to the example embodiment, it is enabled to restrain the change in the film thickness of each of the layers by forming each of the antiferromagnetic layer 74 and the cap layer 75 along the top surface 50a of the MR element 50, the top surface of the ferromagnetic layer 72, and the top surface of the insulating layer 32. Furthermore, it is enabled to more effectively restrain the change in the film thickness of each of the layers by forming each of the antiferromagnetic layer 74 and the cap layer 75 by a method with good step coverage. According to the example embodiment, this also enables to effectively use the antiferromagnetic portion 74a and the protective portion 75a.

Next, a method of forming the plurality of MR elements 50 in the example embodiment will be briefly described. In the process of forming the plurality of MR elements 50, first, a plurality of initial MR elements that later become the plurality of MR elements 50 are formed. Each of the plurality of initial MR elements includes an initial magnetization pinned layer that later becomes the magnetization pinned layer 52, the buffer layer 51, the gap layer 53, the free layer 54, and the cap layer 55.

Next, the magnetization direction of the initial magnetization pinned layer is fixed in a predetermined direction by using laser light and an external magnetic field including a component in the above-described predetermined direction. For example, in a plurality of initial MR elements that later become the plurality of MR elements 50A constituting the resistor sections R11 and R13 of the first detection circuit 10, the plurality of initial MR elements are irradiated with the laser light while being applied with an external magnetic field in the X direction. When the irradiation of the laser light is completed, the magnetization direction of the initial magnetization pinned layer is fixed in the X direction. This causes the initial magnetization pinned layer to become the magnetization pinned layer 52 and the initial MR element to become the MR element 50A.

In a plurality of initial MR elements that later become the plurality of MR elements 50A constituting the resistor sections R12 and R14 of the first detection circuit 10, the magnetization direction of the initial magnetization pinned layer of each of the plurality of initial MR elements can be fixed in the −X direction by using an external magnetic field in the −X direction. In such a manner, the plurality of MR elements 50A are formed. The plurality of MR elements 50B constituting each of the resistor sections R21 to R24 of the second detection circuit 20 are also formed by the same method as with the plurality of MR elements 50A.

Next, a process of fixing the magnetization direction of the ferromagnetic layer 72 is described. The magnetization direction of the ferromagnetic layer 72 is fixed by the same method as with the magnetization pinned layer 52 of the MR element 50. In other words, as described with reference to FIGS. 12A and 12B, first, the antiferromagnetic layer 74 and cap layer 75 are formed, and then the magnetization direction of the ferromagnetic layer 72 is fixed in the above-described predetermined direction using the laser light and the external magnetic field including a component in the predetermined direction. For example, for the plurality of ferromagnetic layers 72 disposed in the vicinity of the plurality of MR elements 50A that later respectively constitute the resistor sections R11 and R12 of the first detection circuit 10, the plurality of ferromagnetic layers 72 are irradiated with the laser light while being applied with an external magnetic field in the Y direction to the plurality of ferromagnetic layers 72. When the irradiation of the laser light is completed, the magnetization direction of the ferromagnetic layer 72 is fixed in the Y direction.

For the plurality of ferromagnetic layers 72 disposed in the vicinity of the plurality of MR elements 50A that respectively later constitute the resistor sections R13 and R14 of the first detection circuit 10, the magnetization direction of each of the plurality of ferromagnetic layers 72 can be fixed in the −Y direction by using an external magnetic field in the −Y direction. The magnetization direction of the plurality of ferromagnetic layers 72, disposed in the vicinity of the plurality of MR elements 50B that respectively constitute the resistor sections R21 to R24 of the second detection circuit 20, is also fixed by the same method mentioned above.

Note that the intensity of the laser light used to fix the magnetization direction of the ferromagnetic layer 72 may be smaller than the intensity of the laser light used to fix the magnetization direction of the magnetization pinned layer 52. The intensity of the laser light used to fix the magnetization direction of the ferromagnetic layer 72 may be an intensity such that the change in magnetoresistive change rate, which is the ratio of the magnetoresistive change to the resistance of the MR element 50, is restrained.

### Modification Examples

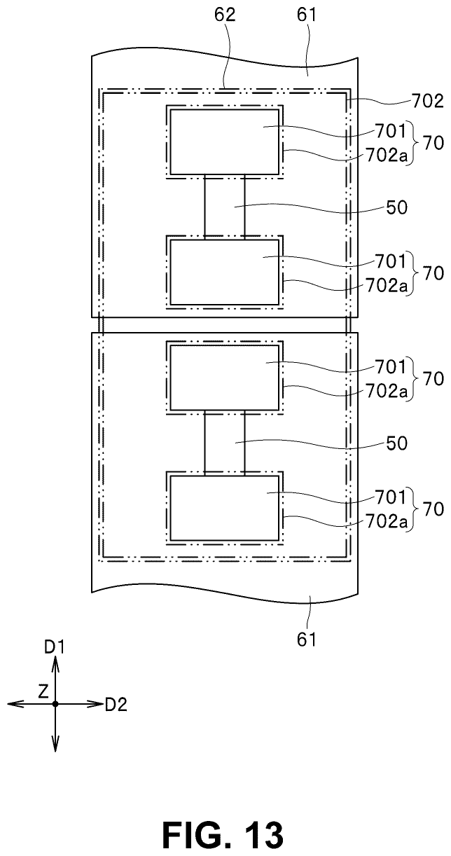

Next, first through seventh modification examples of the magnetic sensor 1 of the example embodiment are described. Initially, the first modification example is described with reference to FIG. 13. FIG. 13 is a plan view showing a main part of the first modification example of the magnetic sensor 1. In the first modification example, each of the plurality of lower electrodes 61 electrically connects two adjacent MR elements 50 in the first direction D1. Each of the plurality of upper electrodes 62 electrically connects two adjacent MR elements 50 disposed on two lower electrodes 61. This connects in series the plurality of MR elements 50 arranged in a row in the first direction D1. In the first modification example, the plurality of connecting electrodes electrically connect the plurality of lower electrodes 61 or the plurality of upper electrodes 62 so that a group of the plurality of MR elements 50 arranged in a row is connected in series.

In the first modification example, the second stack 702 is interposed between the two MR elements 50 arranged in the first direction D1 and the upper electrode 62. The two MR elements 50 are electrically connected also by the antiferromagnetic layer 74 (see FIGS. 9 and 10) of the second stack 702. The two MR elements 50 may be connected in series by the antiferromagnetic layer 74.

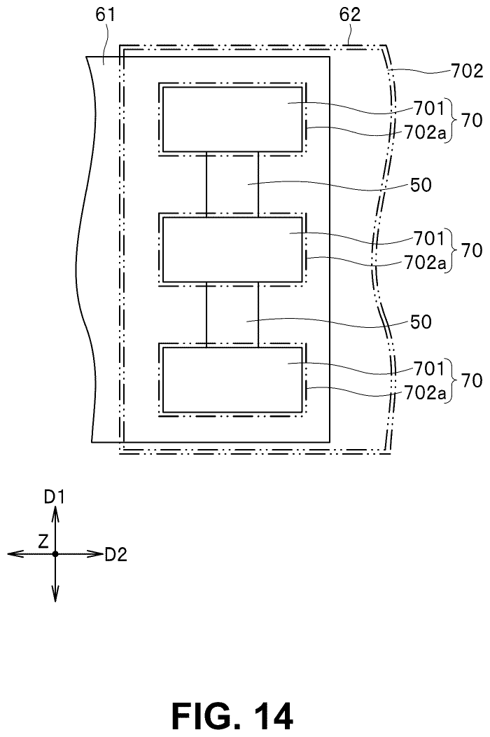

Next, the second modification example is described with reference to FIG. 14. FIG. 14 is a plan view showing a main part of the second modification example of the magnetic sensor 1. In the second modification example, the two MR elements 50 and three magnetic field generators 70 are disposed between the lower electrode 61 and the upper electrode 62. Here, “first”, “second”, and “third” are used to distinguish the three magnetic field generators 70 from each other. The first magnetic field generator 70 is disposed between the two MR elements 50 arranged along the first direction D1. The second magnetic field generator 70 is disposed at a position where one of the two MR elements 50 is interposed between the second magnetic field generator 70 and the first magnetic field generator 70. The third magnetic field generator 70 is disposed at a position where the other of the two MR elements 50 is interposed between the third magnetic field generator 70 and the first magnetic field generator 70.

The two MR elements 50 shown in FIG. 14 may be connected to the same lower electrode 61 and the same upper electrode 62. The two MR elements 50 may be connected in parallel in circuit configuration. Here, the two MR elements 50 connected in parallel in circuit configuration are referred to as an element pair. Each of the plurality of lower electrodes 61 electrically connects two adjacent element pairs in the second direction D2. Each of the plurality of upper electrodes 62 electrically connect the two adjacent element pairs that are disposed on the two lower electrodes 61. This connects in series the plurality of element pairs arranged in a row in the second direction D2.

The second stack 702 is interposed between the two element pairs and the upper electrode 62 electrically connecting the two element pairs. In the second modification example, the second stack 702 is disposed on four MR elements 50 and six first stacks 701. In the second modification example, the second stack 702 includes six stacked parts 702a.

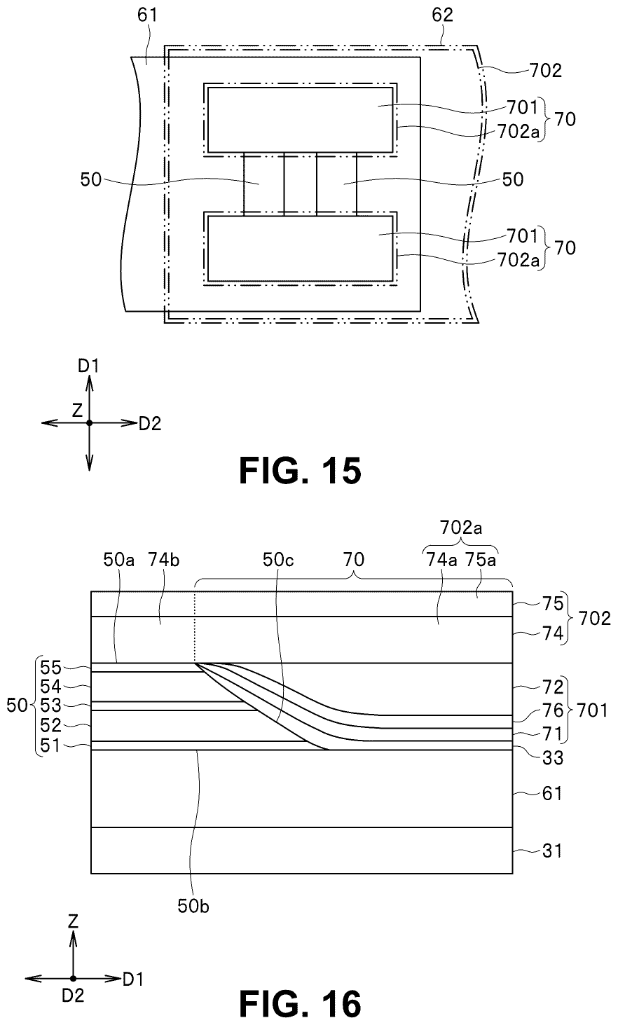

Next, a third modification example is described with reference to FIG. 15. FIG. 15 is a plan view showing a main part of the third modification example of the magnetic sensor 1. In the third modification example, the two MR elements 50 arranged along the second direction D2 are disposed between two magnetic field generators 70 arranged along the first direction D1.

The two MR elements 50 shown in FIG. 15 are connected to the same lower electrode 61 and the same upper electrode 62. The two MR elements 50 constitute an element pair connected in parallel in circuit configuration. Each of the plurality of lower electrodes 61 electrically connects two adjacent element pairs in the second direction D2. Each of the plurality of upper electrodes 62 electrically connects the two adjacent element pairs that are disposed on the two lower electrodes 61. This connects in series the plurality of element pairs arranged in a row in the second direction D2.

The second stack 702 is interposed between the two element pairs and the upper electrode 62 electrically connecting the two element pairs. In the third modification example, the second stack 702 is disposed on four MR elements 50 and four first stacks 701. In the third modification example, the second stack 702 includes four stacked parts 702a.

Next, the fourth modification example is described with reference to FIG. 16. FIG. 16 is a cross-sectional view showing a main part of the fourth modification example of the magnetic sensor 1. In the fourth modification example, the first stack 701 includes, in addition to the buffer layer 71 and the ferromagnetic layer 72, an antiferromagnetic layer 76 disposed between the buffer layer 71 and the ferromagnetic layer 72. The antiferromagnetic layer 76 is formed of an antiferromagnetic material such as, for example, IrMn or PtMn.

The antiferromagnetic layer 76 is in contact with the bottom surface of the ferromagnetic layer 72 to be exchange-coupled with the ferromagnetic layer 72. As previously mentioned, the antiferromagnetic portion 74a is exchange-coupled with the ferromagnetic layer 72. In the fourth modification example, the antiferromagnetic portion 74a and the antiferromagnetic layer 76 are exchange-coupled with the ferromagnetic layer 72 to define the magnetization direction of the ferromagnetic layer 72.

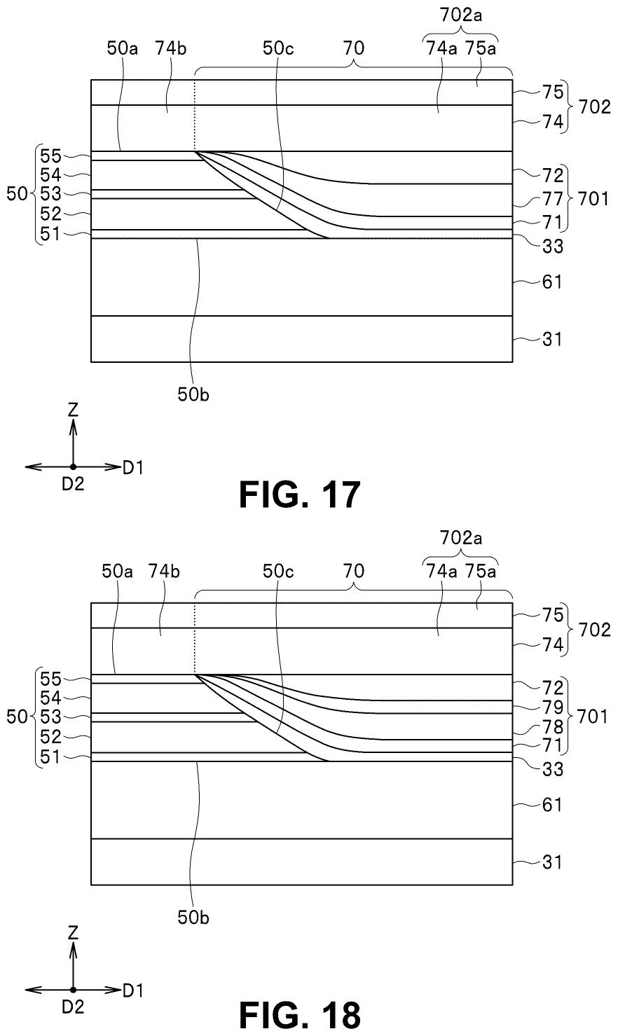

Next, the fifth modification example is described with reference to FIG. 17. FIG. 17 is a cross-sectional view showing a main part of the fifth modification example of the magnetic sensor 1. In the fifth modification example, the first stack 701 includes, in addition to the buffer layer 71 and the ferromagnetic layer 72, a ferromagnetic layer 77 disposed between the buffer layer 71 and the ferromagnetic layer 72. The ferromagnetic layer 77 is formed of a ferromagnetic material containing one or more elements selected from the group consisting of Co, Fe, and Ni. In the fifth modification example, the ferromagnetic layer 77 has magnetization in the same direction as the magnetization of the ferromagnetic layer 72.

In the fifth modification example, the ferromagnetic layer 72 may be formed of a ferromagnetic material that can increase the exchange coupling energy between the ferromagnetic layer 72 and the antiferromagnetic portion 74a, and the ferromagnetic layer 77 may be formed of a ferromagnetic material having a saturation magnetic flux density larger than that of the ferromagnetic material constituting the ferromagnetic layer 72. In this case, the strength of the bias magnetic field generated by the magnetic field generator 70 can be increased while increasing the exchange coupling energy between the ferromagnetic portion formed of the ferromagnetic layers 72 and 77 and the antiferromagnetic portion 74a, and the magnetic field generator 70 can be made smaller. An example of the ferromagnetic layer 72 includes a Co₇₀Fe₃₀ layer. An example of the ferromagnetic layer 77 includes a Co₃₀Fe₇₀ layer.

Next, the sixth modification example is described with reference to FIG. 18. FIG. 18 is a cross-sectional view showing a main part of the sixth modification example of the magnetic sensor 1. In the sixth modification example, the first stack 701 includes, in addition to the buffer layer 71 and the ferromagnetic layer 72, a ferromagnetic layer 78 disposed between the buffer layer 71 and the ferromagnetic layer 72 and a nonmagnetic layer 79 disposed between the ferromagnetic layer 72 and the ferromagnetic layer 78. The ferromagnetic layer 78 is formed of a ferromagnetic material containing one or more elements selected from the group consisting of Co, Fe, and Ni. The ferromagnetic layer 72 and the ferromagnetic layer 78 may be formed of the same ferromagnetic material or different ferromagnetic materials. The nonmagnetic layer 79 is formed of a nonmagnetic metallic material such as, for example, Ru.

In the sixth modification example, the ferromagnetic layer 72 and the ferromagnetic layer 78 are ferromagnetically exchange-coupled via the nonmagnetic layer 79 so as to have the same magnetization direction. The ferromagnetic layer 72 and the ferromagnetic layer 78 have magnetization in the same direction. The thickness of the nonmagnetic layer 79 is set to a thickness so as not to lose the exchange coupling between the ferromagnetic layer 72 and the ferromagnetic layer 78.

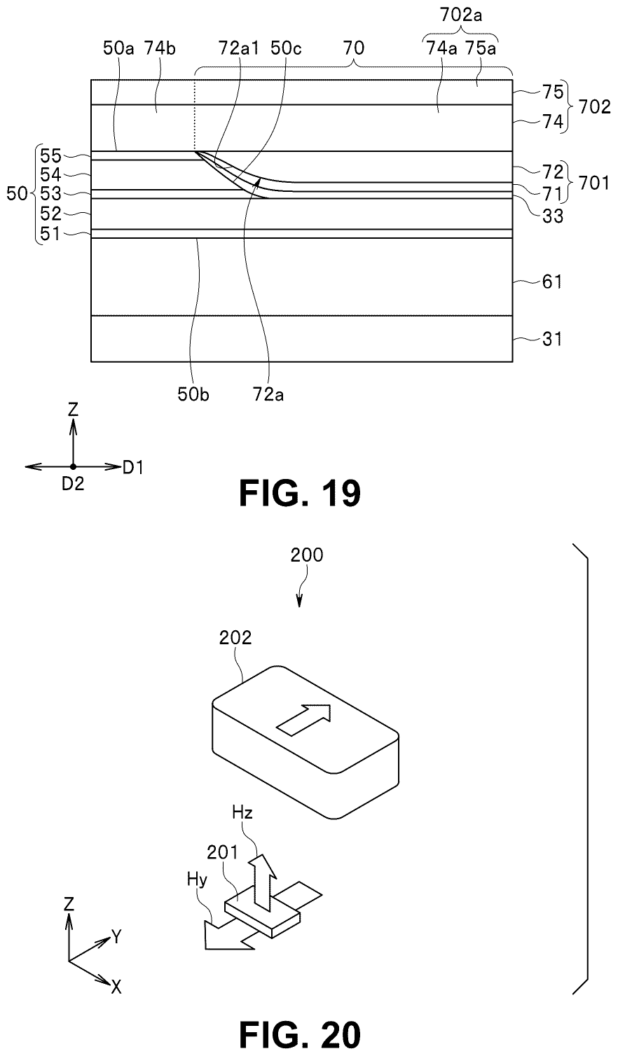

Next, the seventh modification example is described with reference to FIG. 19. In the seventh modification example, the two side surfaces 50c of the MR element 50 are formed by etching at least the gap layer 53, the free layer 54, and the cap layer 55 in the process of patterning the stacked film described with reference to FIG. 12A. In this process, a part of the magnetization pinned layer 52 may or may not be etched.

In the seventh modification example, the ferromagnetic layer 72 is disposed to ride up on the side surface 50c of the MR element 50 and on the magnetization pinned layer 52. The insulating layer 33 is formed along the side surface 50c of the MR element 50 and the top surface of the magnetization pinned layer 52.

Note that the first through seventh modification examples may be arbitrarily combined. For example, the first modification example shown in FIG. 13 may be combined with the second modification example shown in FIG. 14 or the third modification example shown in FIG. 15. In this case, two pairs of the MR elements 50 adjacent in the first direction D1 are electrically connected.

### Second Example Embodiment

Next, a second example embodiment of the disclosure is described. Initially, a configuration of a magnetic sensor system including a magnetic sensor according to the example embodiment is described with reference to FIG. 20. FIG. 20 is a perspective view showing a magnetic sensor system 200 in the example embodiment.

The magnetic sensor system 200 includes a magnetic sensor 201 according to the example embodiment and a magnetic field generation section 202 that generates a predetermined magnetic field. In the example embodiment, the magnetic field generation section 202 is a magnet configured such that a partial magnetic field, which is a part of the generated magnetic field, is applied to the magnetic sensor 201. This partial magnetic field includes a first magnetic field component Hz parallel to the Z direction and a second magnetic field component Hy parallel to the Y direction.

As shown in FIG. 20, in the example embodiment, the magnetization direction of the magnetic field generation section 202 is the Y direction, and the direction of the second magnetic field component Hy is the −Y direction. The direction of the first magnetic field component Hz is the Z direction when the magnetic field generation section 202 moves in the Y direction from a predetermined position, and is the −Z direction when the magnetic field generation section 202 moves in the −Y direction from the predetermined position.

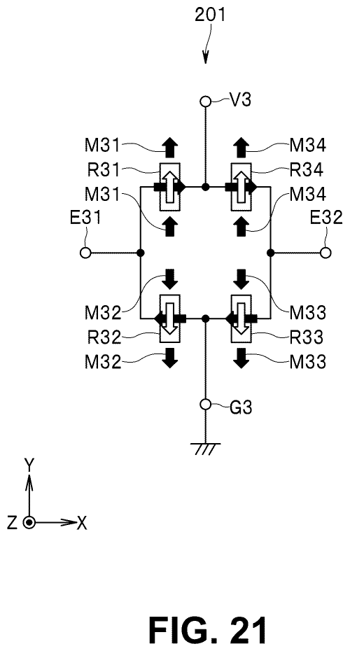

Next, a schematic configuration of the magnetic sensor 201 according to the example embodiment is described with reference to FIG. 21. FIG. 21 is a circuit diagram showing a circuit configuration of the magnetic sensor 201.

The magnetic sensor 201 includes four resistor sections R31, R32, R33, and R34, a power supply port V3, a ground port G3, and two output ports E31 and E32. The resistor section R31 is provided between the power supply port V3 and the output port E31. The resistor section R32 is provided between the output port E31 and the ground port G3. The resistor section R33 is provided between the output port E32 and the ground port G3. The resistor section R34 is provided between the power supply port V3 and the output port E32. A voltage or current of a predetermined magnitude is applied to the power supply port V3. The ground port G3 is connected to ground.

Each of the resistor sections R31 to R34 includes the plurality of MR elements 50. The configuration of the plurality of MR elements 50 is the same as in the first example embodiment. In other words, each of the plurality of MR elements 50 includes the buffer layer 51, the magnetization pinned layer 52, the gap layer 53, the free layer 54, and the cap layer 55, as shown in FIGS. 9 and 10 in the first example embodiment.

In FIG. 21, a plurality of solid arrows drawn to overlap the resistor sections R31 to R34, respectively, represent the magnetization direction of the magnetization pinned layer 52 in each of the resistor sections R31 to R34. In the example shown in FIG. 21, the direction of the main component of the magnetization of the magnetization pinned layer 52 in each of the resistor sections R31 and R34 is the X direction. The direction of the main component of the magnetization of the magnetization pinned layer 52 in each of the resistor sections R32 and R33 is the −X direction. The free layer 54 in each of the resistor sections R31 to R34 has shape anisotropy in which the direction of the magnetization easy axis is parallel to the Y direction.

Each of the resistor sections R31 to R34 further includes the plurality of magnetic field generators 70. The configuration of the plurality of magnetic field generators 70 is the same as in the first example embodiment. The plurality of magnetic field generators 70 include a plurality of pairs of the magnetic field generators 70, each pair including two magnetic field generators 70. The two magnetic field generators 70 are disposed at a distance from each other in a direction parallel to the Y direction with one MR element 50 interposed therebetween. The two magnetic field generators 70 are configured to apply a bias magnetic field to the one MR element 50 located therebetween. This bias magnetic field includes, as the main component, a component parallel to the Y direction.

In FIG. 21, arrows labelled with the reference numerals M31, M32, M33, and M34 indicate the directions of the main components of the bias magnetic fields generated by the plurality of magnetic field generators 70 in the resistor sections R31, R32, R33, and R34, respectively. The directions of the main components of the bias magnetic fields at the resistor sections R31 and R34 are each the Y direction. The directions of the main components of the bias magnetic fields at the resistor sections R32 and R33 are each the −Y direction.

In FIG. 21, the plurality of hollow arrows drawn to overlap the resistor sections R31 to R34, respectively, represent the magnetization direction of the free layer in each of the resistor sections R31 to R34 when the partial magnetic field is not applied to the magnetic sensor 201. The direction of the main component of the magnetization of the free layer in each of the resistor sections R31 and R34 is the Y direction, and is the same as the direction of the main component of the bias magnetic field at the resistor sections R31 and R34. The direction of the main component of the magnetization of the free layer in each of resistor sections R32 and R33 is the −Y direction, and is the same as the direction of the main component of the bias magnetic field at the resistor sections R32 and R33.

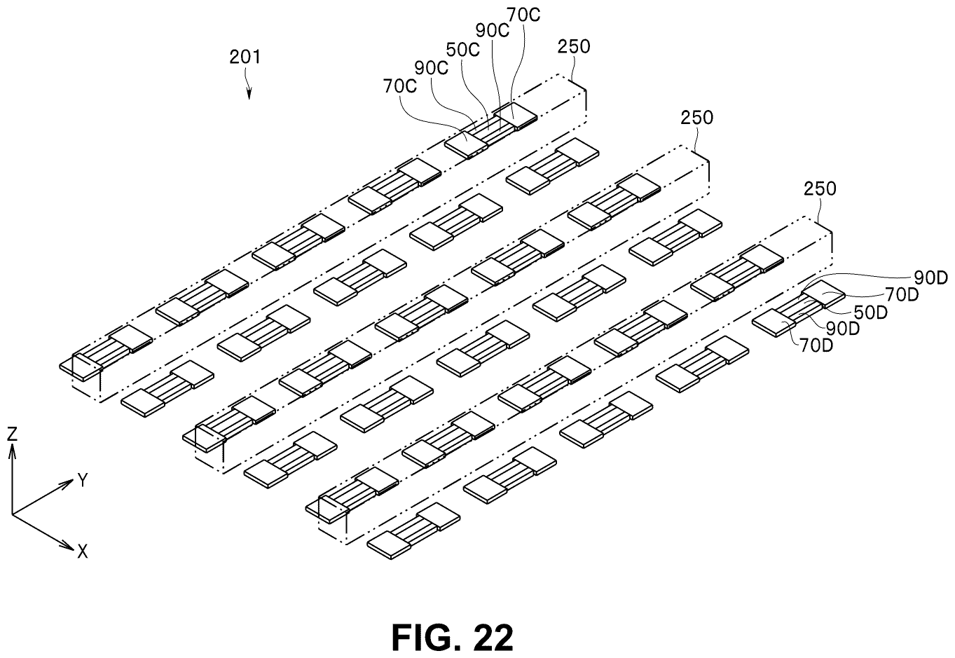

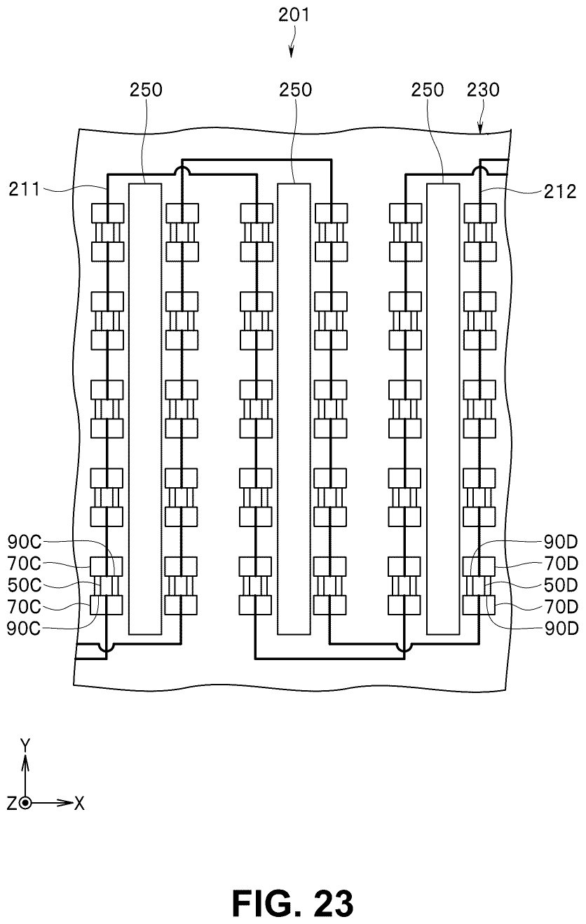

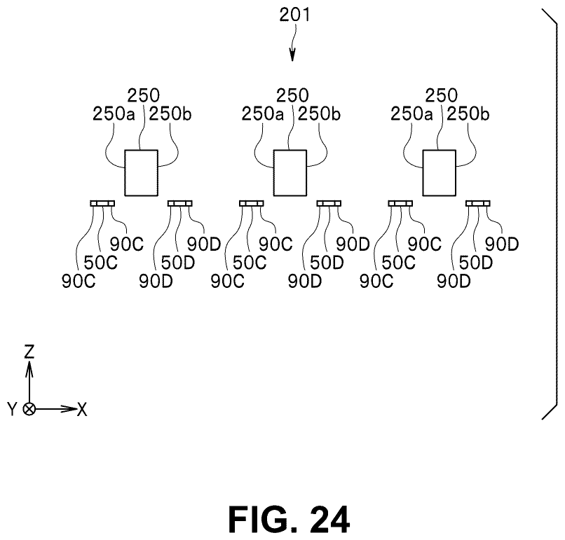

Next, a configuration of the magnetic sensor 201 is specifically described with reference to FIGS. 22 through 24. FIG. 22 is a perspective view showing a part of the magnetic sensor 201. FIG. 23 is a plan view showing a part of the magnetic sensor 201. FIG. 24 is a side view showing a part of the magnetic sensor 201.

The magnetic sensor 201 further includes a substrate 230. The magnetic sensor 201 is constituted by forming a plurality of components other than the substrate 230 on the substrate 230.

The magnetic sensor 201 further includes at least one yoke made of a soft magnetic material. The at least one yoke has a shape long in the Y direction when viewed in the Z direction. The at least one yoke generates a magnetic field component in a direction parallel to the X direction based on the first magnetic field component Hz shown in FIG. 20.

As shown in FIGS. 22 through 24, in the example embodiment in particular, the magnetic sensor 201 includes, as the at least one yoke, a plurality of yokes 250 disposed to be arranged in the X direction. Each of the plurality of yokes 250 has, for example, a rectangular parallelepiped shape long in the Y direction. The plurality of yokes 250 has a same shape. Each of the plurality of yokes 250 has a first end surface 250a and a second end surface 250b located at both ends in a direction parallel to the X direction. In each of the plurality of yokes 250, the first end surface 250a is located at an end in the −X direction and the second end surface 250b is located at an end in the X direction.

Each of the plurality of MR elements 50 is disposed at a position where a magnetic field component generated by the plurality of yokes 250 is applied thereto. In the example embodiment in particular, each of the MR elements 50 is disposed in the vicinity of an end of each of the plurality of yokes 250 in the −Z direction. The plurality of MR elements 50 are disposed such that a group of the plurality of MR elements 50 are arranged along the first end surface 250a or the second end surface 250b of each of the plurality of yokes 250. Hereinafter, of the plurality of MR elements 50, a plurality of MR elements arranged along the first end surface 250a are denoted by the reference numeral 50C, and a plurality of MR elements arranged along the second end surface 250b are denoted by the reference numeral 50D. The direction of the magnetic field component received by the plurality of MR elements 50C and the direction of the magnetic field component received by the plurality of MR elements 50D are opposite to each other.

The plurality of MR elements 50C and the plurality of MR elements 50D may or may not overlap the plurality of yokes 250 when viewed in the Z direction. In the examples shown in FIGS. 22 through 24, the plurality of MR elements 50C and the plurality of MR elements 50D are disposed so as not to overlap the plurality of yokes 250 when viewed in the Z direction.

As shown in FIGS. 22 and 23, of the plurality of magnetic field generators 70, a plurality of magnetic field generators disposed with an MR element 50C interposed therebetween is denoted by the reference numeral 70C, and a plurality of magnetic field generators disposed with an MR element 50D interposed therebetween is denoted by the reference numeral 70D. The magnetic sensor 201 further includes a plurality of yokes 90C and a plurality of yokes 90D, each including a magnetic layer made of a soft magnetic material. The plurality of yokes 90C include a plurality of pairs of yokes 90C, each pair including two yokes 90C. The two yokes 90C are disposed on both sides of one MR element 50C in a direction parallel to the X direction. The plurality of yokes 90D includes a plurality of pairs of yokes 90D, each pair including two yokes 90D. The two yokes 90D are disposed on both sides of one MR element 50D in a direction parallel to the X direction.

The plurality of yokes 90C have a function of guiding magnetic field components generated by the plurality of yokes 250 to the plurality of MR elements 50C. The plurality of yokes 90D have a function of guiding the magnetic field components generated by the plurality of yokes 250 to the plurality of MR elements 50D.

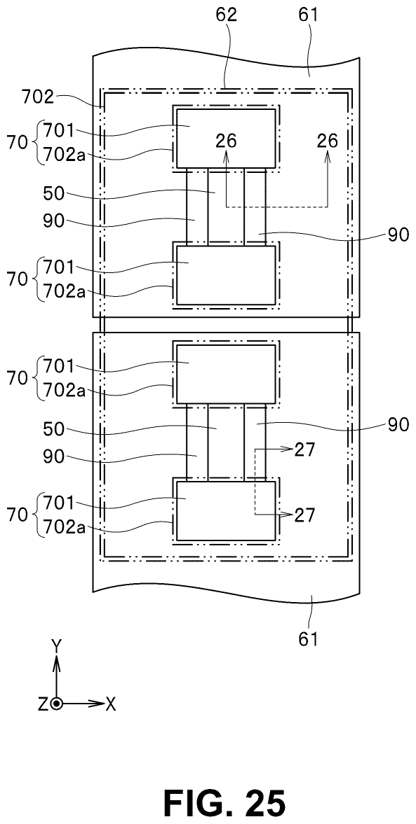

The magnetic sensor 201 further includes a wiring portion 211 electrically connecting the plurality of MR elements 50C and a wiring portion 212 electrically connecting the plurality of MR elements 50D. Each of the wiring portions 211 and 212 is constituted of the plurality of lower electrodes 61 and the plurality of upper electrodes 62, and the plurality of connecting electrodes. Note that the lower electrode 61 and the upper electrode 62 are shown in FIGS. 25 through 27, which will be described later.

The wiring portion 211 includes a first wiring electrically connecting the plurality of MR elements 50C in which the direction of the main component of the magnetization of the magnetization pinned layer 52 is the X direction, and a second wiring electrically connecting the plurality of MR elements 50C in which the direction of the main component of the magnetization of the magnetization pinned layer 52 is the −X direction. The resistor section R31 is constituted of the plurality of MR elements 50C electrically connected by the first wiring. The resistor section R32 is constituted of the plurality of MR elements 50C electrically connected by the second wiring.

The wiring portion 212 includes a third wiring electrically connecting the plurality of MR elements 50D in which the direction of the main component of the magnetization of the each magnetization pinned layer 52 is the −X direction, and a fourth wiring electrically connecting the plurality of MR elements 50D in which the direction of the main component of the magnetization of the each magnetization pinned layer 52 is the X direction. The resistor section R33 is constituted of the plurality of MR elements 50D electrically connected by the third wiring. The resistor section R34 is constituted of the plurality of MR elements 50D electrically connected by the fourth wiring.

Next, an operation of the magnetic sensor 201 is described. In a state where a first magnetic field component Hz is not present and consequently magnetic field components generated by the plurality of yokes 250 are also not present, the magnetization direction of the free layer 54 of each of the plurality of MR elements 50C and the plurality of MR elements 50D is a direction parallel to the Y direction.

When the direction of the first magnetic field component Hz is the Z direction, the direction of the magnetic field component received by each of the plurality of MR elements 50C constituting the resistor sections R31 and R32 is the X direction, and the direction of the magnetic field component received by each of the plurality of MR elements 50D constituting the resistor sections R33 and R34 is the −X direction. In this case, the magnetization direction of the free layer 54 of each of the plurality of MR elements 50C is inclined from a direction parallel to the Y direction to the X direction, and the magnetization direction of the free layer 54 of each of the plurality of MR elements 50D is inclined from a direction parallel to the Y direction to the −X direction. As a result, compared to a state in which no magnetic field component is present, the resistance value of each of the plurality of MR elements 50C constituting the resistor section R31 and the resistance value of each of the plurality of MR elements 50D constituting the resistor section R33 decrease, and the resistance value of each of the plurality of MR elements 50C constituting the resistor section R32 and the resistance value of each of the plurality of MR elements 50D constituting the resistor section R34 increase. As a result, the resistance values of the resistor sections R31 and R33 decrease and the resistance values of the resistor sections R32 and R34 increase.

If the direction of the first magnetic field component Hz is the −Z direction, the direction of the magnetic field component and the change in the resistance value of each of the resistor sections R31 to R34 are opposite to the above-mentioned case where the direction of the first magnetic field component Hz is the Z direction.

The amount of change in the resistance value of each of the resistor sections R31 to R34 depends on the strength of the magnetic field component received by each of the plurality of MR elements 50C and the plurality of MR elements 50D. When the strength of the magnetic field component increases, the resistance value of each of the resistor sections R31 to R34 changes such that the amount of increase or the amount of decrease of the resistance value becomes larger. When the strength of the magnetic field component become smaller, the resistance value of each of the resistor sections R31 to R34 changes such that the amount of increase or the amount of decrease of the resistance value becomes smaller. The strength of the magnetic field component depends on the strength of the first magnetic field component Hz.

Thus, when the direction and strength of the first magnetic field component Hz change, the resistance value of each of the resistor sections R31 to R34 changes either such that the resistance value of each of the resistor sections R31 and R33 increases and the resistance value of each of the resistor sections R32 and R34 decreases, or such that the resistance value of each of the resistor sections R31 and R33 decreases and the resistance value of each of the resistor sections R32 and R34 increases. This changes the potential of the connection point between the resistor sections R31 and R32, i.e., the potential of the output port E31, and the potential of the connection point between the resistor sections R33 and R34, i.e., the potential of the output port E32. The magnetic sensor 201 may generate a signal corresponding to the potential of the output port E31 and a signal corresponding to the potential of the output port E32, each as a detection signal. Alternatively, the magnetic sensor 201 may generate a signal corresponding to the potential difference between the output ports E31 and E32 as a detection signal. In this case, the magnetic sensor 201 may further include a differential amplifier (difference detector) that outputs the signal corresponding to the potential difference between the output ports E31 and E32 as a detection signal.

The magnetic sensor system 200 may further include the processor 2 shown in FIGS. 1 and 2 in the first example embodiment. The processor 2 may be configured to receive one detection signal or two detection signals output from the magnetic sensor 201 to generate a detection value having a correspondence with the strength of the first magnetic field component Hz or a detection value having a correspondence with the position of the magnetic field generation section 202 (see FIG. 20).

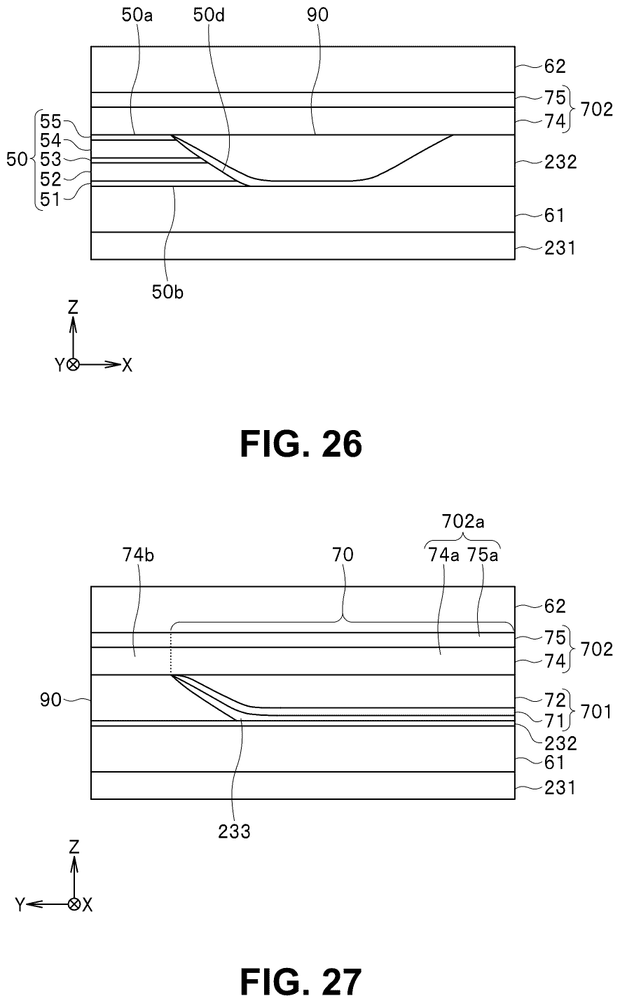

Next, the plurality of yokes 90C and the plurality of yokes 90D are described in detail with reference to FIGS. 25 through 27. FIG. 25 is a plan view showing a main part of the magnetic sensor 201. FIG. 26 is a cross-sectional view showing a part of a cross section at a position indicated by a 26-26 line in FIG. 25. FIG. 27 is a cross-sectional view showing a part of a cross section at a position indicated by a 27-27 line in FIG. 25.

Hereinafter, any yoke of the plurality of yokes 90C and the plurality of yokes 90D is denoted using the reference numeral 90. The configuration and shape of each of the MR element 50 and the magnetic field generator 70, and the positional relationship between the MR element 50 and the magnetic field generator 70 are the same as in the first example embodiment. The configuration and shape of each of the first and second stacks 701 and 702 and the positional relationship between the MR element 50 and the first and second stacks 701 and 702 are also the same as in the first example embodiment.

Here, a configuration of a yoke 90 is described with a focus on one MR element 50. Two yokes 90 are disposed on both sides of the MR element 50 in a direction parallel to the X direction. The magnetic sensor 201 further includes an insulating layer 232 made of an insulating material such as Al₂O₃ or SiO₂. The insulating layer 232 is disposed on both sides of the MR element 50 in a direction parallel to the X direction. In the example embodiment in particular, the insulating layer 232 is disposed around the MR element 50 and the ferromagnetic layer 72 of the magnetic field generator 70.

The two yokes 90 are embedded in the insulating layer 232. The insulating layer 232 is interposed between the MR element 50 and the two yokes 90 and between the lower electrode 61 and the two yokes 90. Each of the two yokes 90 may include, in addition to the magnetic layer, a buffer layer interposed between the magnetic layer and the insulating layer 232, and a cap layer disposed on the magnetic layer. The buffer layer and the cap layer may be formed of a nonmagnetic metallic material, for example. Each of the two yokes 90 is disposed to ride up on the side surface 50d of the MR element 50. A part of each of the two yokes 90 overlaps a part of the MR element 50 when viewed in the Z direction.

The two yokes 90 are disposed between the two magnetic field generators 70, which are disposed at a distance from each other in a direction parallel to the Y direction. The ferromagnetic layer 72 of the magnetic field generator 70 (first stack 701) is disposed to overlap the two yokes 90 when viewed in the Y or −Y direction.

The ferromagnetic layer 72 is disposed to ride up on the yoke 90. A part of the ferromagnetic layer 72 overlaps a part of the yoke 90 when viewed in the Z direction. The magnetic sensor 201 further includes an insulating layer 233 made of an insulating material such as Al₂O₃ or SiO₂ and interposed between the ferromagnetic layer 72 and the yoke 90. A part of the buffer layer 71 of the magnetic field generator 70 (first stack 701) is interposed between the ferromagnetic layer 72 and the insulating layer 233.

In the example embodiment, the antiferromagnetic layer 74 is disposed on the MR element 50, the two ferromagnetic layers 72, the two yokes 90, and the insulating layer 232. The top surface of each of the two yokes 90 may be in contact with the antiferromagnetic layer 74. The magnetic sensor 201 further includes an insulating layer 231 made of an insulating material such as Al₂O₃ or SiO₂ and interposed between the substrate 230 (see FIG. 23) and the lower electrode 61, and an insulating layer (not shown) made of an insulating material and disposed on the upper electrode 62.

The configuration, operation, and effects of the present example embodiment are otherwise the same as those of the first example embodiment.

### Third Example Embodiment

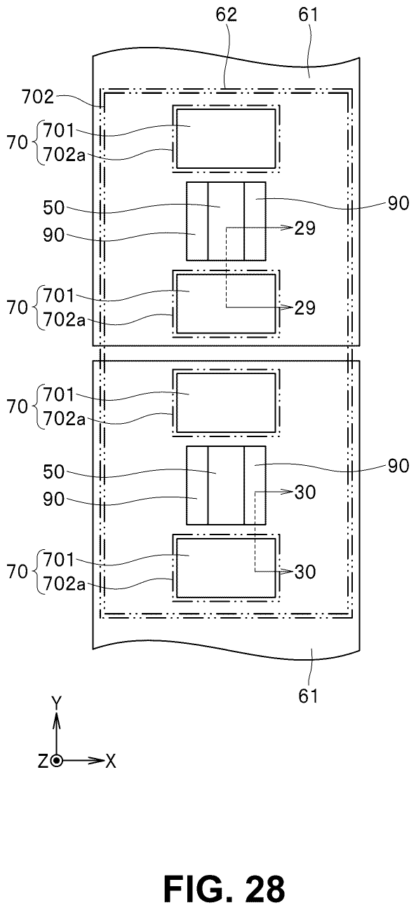

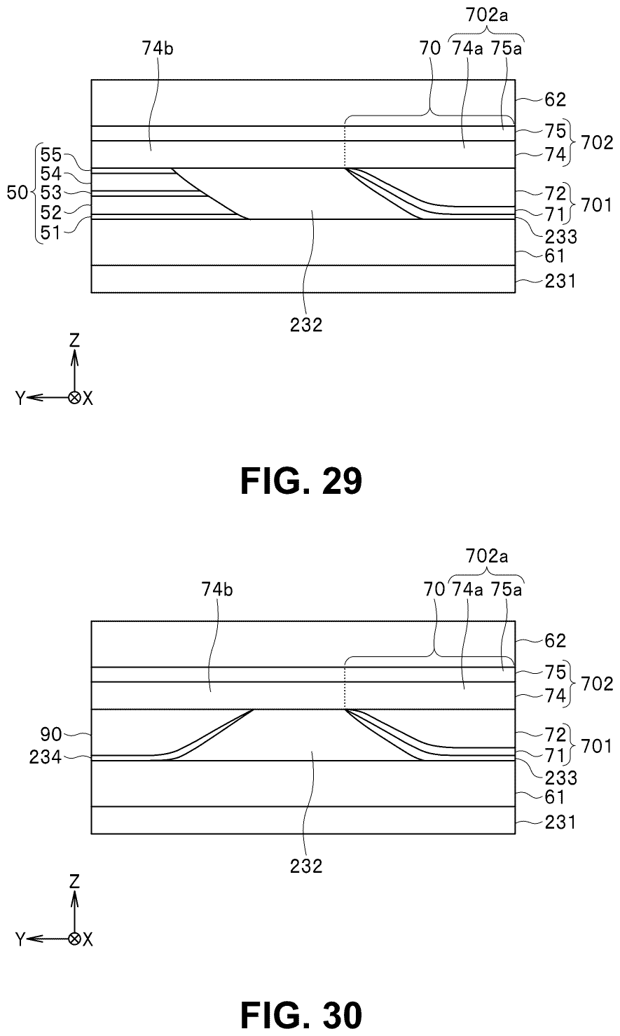

Next, a third example embodiment of the disclosure is described with reference to FIGS. 28 through 30. FIG. 28 is a plan view showing a main part of a magnetic sensor according to the example embodiment. FIG. 29 is a cross-sectional view showing a part of a cross section at a position indicated by a 29-29 line in FIG. 28. FIG. 30 is a cross-sectional view showing a part of a cross section at a position indicated by a 30-30 line in FIG. 28.

The following describes, with a focus on one MR element 50, how the configuration of the magnetic sensor 201 according to the example embodiment differs from the second example embodiment. In the example embodiment, each of the two magnetic field generators 70 is disposed at a distance from the MR element 50. Therefore, the ferromagnetic layer 72 of each of the two magnetic field generators 70 is disposed at a distance from the MR element 50.

Each of the two magnetic field generators 70 is disposed at a distance from the two yokes 90. Therefore, the ferromagnetic layer 72 of each of the two magnetic field generators 70 is disposed at a distance from the two yokes 90.

In the example embodiment, the insulating layer 233 is interposed between the ferromagnetic layer 72, and the lower electrode 61 and the insulating layer 232. The magnetic sensor 201 further includes an insulating layer 234 made of an insulating material such as Al₂O₃ or SiO₂ and interposed between the two yokes 90, and the lower electrode 61 and the insulating layer 232.

The configuration, operation, and effects of the present example embodiment are otherwise the same as those of the second example embodiment.

The disclosure is not limited to the foregoing example embodiments, and various modifications may be made thereto. For example, the magnetic sensor of the disclosure may be a magnetic sensor including the first and second detection circuits 10 and 20 in the first example embodiment, and the magnetic sensor 201 according to the second example embodiment as a third detection circuit. In this magnetic sensor, the third detection circuit (magnetic sensor 201) may be also configured to detect a component in a direction parallel to the Z direction of the target magnetic field. This magnetic sensor may be a geomagnetic sensor that detects the geomagnetic field as the target magnetic field.

The MR element 50 may be constituted of the buffer layer 51, the free layer 54, the gap layer 53, the magnetization pinned layer 52, and the cap layer 55, stacked in this order from the lower electrode 61 side.

As described above, a magnetic sensor according to one embodiment of the disclosure includes: at least one magnetoresistive element including a plurality of magnetic films stacked on each other; a first ferromagnetic layer made of a ferromagnetic material, the first ferromagnetic layer being disposed to overlap the at least one magnetoresistive element when viewed in a first direction orthogonal to a stacking direction of the plurality of magnetic films; an insulating layer made of an insulating material, the insulating layer being disposed on both sides of the at least one magnetoresistive element in a second direction orthogonal to each of the stacking direction and the first direction; and an antiferromagnetic layer disposed on the at least one magnetoresistive element, the first ferromagnetic layer, and the insulating layer. The antiferromagnetic layer includes a first antiferromagnetic portion that faces the first ferromagnetic layer, and a non-facing part that faces the at least one magnetoresistive element and the insulating layer but does not face the first ferromagnetic layer. No magnetic layer is present between the at least one magnetoresistive element and the antiferromagnetic layer.

In the magnetic sensor according to one embodiment of the disclosure, the first ferromagnetic layer and the first antiferromagnetic portion may constitute a magnetic field generator that generates a magnetic field to be applied to the at least one magnetoresistive element.

In the magnetic sensor according to one embodiment of the disclosure, the at least one magnetoresistive element may include a first magnetoresistive element and a second magnetoresistive element. The first magnetoresistive element and the second magnetoresistive element may be connected in series via the antiferromagnetic layer. The first magnetoresistive element and the second magnetoresistive element may be arranged along the first direction. Alternatively, the first magnetoresistive element and the second magnetoresistive element may be arranged along the second direction.

The magnetic sensor according to one embodiment of the disclosure may further include a second ferromagnetic layer made of a ferromagnetic material, the second ferromagnetic layer being disposed at a position where the at least one magnetoresistive element is interposed between the second ferromagnetic layer and the first ferromagnetic layer in the first direction. The antiferromagnetic layer may further include a second antiferromagnetic portion that faces the second ferromagnetic layer. The first ferromagnetic layer and the first antiferromagnetic portion may constitute a first magnetic field generator that generates a first magnetic field to be applied to the at least one magnetoresistive element. The second ferromagnetic layer and the second antiferromagnetic portion may constitute a second magnetic field generator that generates a second magnetic field to be applied to the at least one magnetoresistive element. The at least one magnetoresistive element may include a first magnetoresistive element and a second magnetoresistive element. The first magnetoresistive element and the second magnetoresistive element may be connected in parallel in circuit configuration.

In the magnetic sensor according to one embodiment of the disclosure, the antiferromagnetic layer may be in contact with the at least one magnetoresistive element. The at least one magnetoresistive element may further include a nonmagnetic metal layer that is interposed between the antiferromagnetic layer and the plurality of magnetic films and that is in contact with the antiferromagnetic layer.

In the magnetic sensor according to one embodiment of the disclosure, the plurality of magnetic films may include a free layer having a magnetization whose direction is variable depending on a target magnetic field. The first ferromagnetic layer may include a side surface that faces the at least one magnetoresistive element. The side surface may include an inclined part that faces the free layer, the inclined part being inclined with respect to the stacking direction. The angle that the inclined part forms with respect to the stacking direction may be within a range equal to or larger than 20° and equal to or smaller than 90°.

In the magnetic sensor according to one embodiment of the disclosure, the at least one magnetoresistive element may include a first surface that faces the non-facing part and a second surface opposite the first surface. The distance between at least a part of the non-facing part and the second surface may be the same as the distance between the first surface and the second surface.

The magnetic sensor according to one embodiment of the disclosure may further include two yokes disposed on both sides of the at least one magnetoresistive element in the second direction, each of the two yokes being made of a soft magnetic material. The antiferromagnetic layer may be disposed on the at least one magnetoresistive element, the first ferromagnetic layer, the insulating layer, and the two yokes.

The magnetic sensor according to one embodiment of the disclosure may further include a first port, a second port, a third port, a first resistor section disposed between the first port and the second port in circuit configuration, and a second resistor section disposed between the second port and the third port in circuit configuration. Each of the first resistor section and the second resistor section may include the at least one magnetoresistive element, the first ferromagnetic layer, the insulating layer, and the antiferromagnetic layer. The plurality of magnetic films may include a free layer having a magnetization whose direction is variable depending on a target magnetic field. In the first resistor section, the first ferromagnetic layer and the first antiferromagnetic portion may constitute a first magnetic field generator that generates a first magnetic field to be applied to the at least one magnetoresistive element. In the second resistor section, the first ferromagnetic layer and the first antiferromagnetic portion may constitute a second magnetic field generator that generates a second magnetic field to be applied to the at least one magnetoresistive element. The first magnetic field may include, as a main component, a component in a first magnetic field direction that is one direction parallel to the first direction. The second magnetic field may include, as a main component, a component in a second magnetic field direction opposite to the first magnetic field direction. In the first resistor section, the magnetization of the free layer may include a component in the first magnetic field direction in a case where the target magnetic field is not applied to the magnetic sensor. In the second resistor section, the magnetization of the free layer may include a component in the second magnetic field direction in a case where the target magnetic field is not applied to the magnetic sensor.

In the magnetic sensor of the disclosure, the antiferromagnetic layer is disposed on the at least one magnetoresistive element, and the first ferromagnetic layer, and the insulating layer. The antiferromagnetic layer includes a first antiferromagnetic portion that faces the first ferromagnetic layer, and a non-facing part that faces the at least one magnetoresistive element and the insulating layer but does not face the first ferromagnetic layer. No magnetic layer is present between the at least one magnetoresistive element and the antiferromagnetic layer. According to the disclosure, this enables to restrain a reduction in the sensitivity of the magnetoresistive element.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A magnetic sensor comprising:
at least one magnetoresistive element including a plurality of magnetic films stacked on each other;
a first ferromagnetic layer made of a ferromagnetic material, the first ferromagnetic layer being disposed to overlap the at least one magnetoresistive element when viewed in a first direction orthogonal to a stacking direction of the plurality of magnetic films;
an insulating layer made of an insulating material, the insulating layer being disposed on both sides of the at least one magnetoresistive element in a second direction orthogonal to each of the stacking direction and the first direction; and
an antiferromagnetic layer disposed on the at least one magnetoresistive element, the first ferromagnetic layer, and the insulating layer, wherein
the antiferromagnetic layer includes a first antiferromagnetic portion that faces the first ferromagnetic layer, and a non-facing part that faces the at least one magnetoresistive element and the insulating layer but does not face the first ferromagnetic layer, and
no magnetic layer is present between the at least one magnetoresistive element and the antiferromagnetic layer.

2. The magnetic sensor according to claim 1, wherein the first ferromagnetic layer and the first antiferromagnetic portion constitute a magnetic field generator that generates a magnetic field to be applied to the at least one magnetoresistive element.

3. The magnetic sensor according to claim 1, wherein
the at least one magnetoresistive element comprises a first magnetoresistive element and a second magnetoresistive element, and
the first magnetoresistive element and the second magnetoresistive element are connected in series via the antiferromagnetic layer.

4. The magnetic sensor according to claim 3, wherein the first magnetoresistive element and the second magnetoresistive element are arranged along the first direction.

5. The magnetic sensor according to claim 3, wherein the first magnetoresistive element and the second magnetoresistive element are arranged along the second direction.

6. The magnetic sensor according to claim 1, further comprising:
a second ferromagnetic layer made of a ferromagnetic material, the second ferromagnetic layer being disposed at a position where the at least one magnetoresistive element is interposed between the second ferromagnetic layer and the first ferromagnetic layer in the first direction, wherein
the antiferromagnetic layer further includes a second antiferromagnetic portion that faces the second ferromagnetic layer,
the first ferromagnetic layer and the first antiferromagnetic portion constitute a first magnetic field generator that generates a first magnetic field to be applied to the at least one magnetoresistive element, and
the second ferromagnetic layer and the second antiferromagnetic portion constitute a second magnetic field generator that generates a second magnetic field to be applied to the at least one magnetoresistive element.

7. The magnetic sensor according to claim 6, wherein
the at least one magnetoresistive element comprises a first magnetoresistive element and a second magnetoresistive element, and
the first magnetoresistive element and the second magnetoresistive element are connected in parallel in circuit configuration.

8. The magnetic sensor according to claim 1, wherein the antiferromagnetic layer is in contact with the at least one magnetoresistive element.

9. The magnetic sensor according to claim 8, wherein the at least one magnetoresistive element further includes a nonmagnetic metal layer that is interposed between the antiferromagnetic layer and the plurality of magnetic films and that is in contact with the antiferromagnetic layer.

10. The magnetic sensor according to claim 1, wherein
the plurality of magnetic films include a free layer having a magnetization whose direction is variable depending on a target magnetic field,
the first ferromagnetic layer includes a side surface that faces the at least one magnetoresistive element,
the side surface includes an inclined part that faces the free layer, the inclined part being inclined with respect to the stacking direction, and
an angle that the inclined part forms with respect to the stacking direction is within a range equal to or larger than 20° and equal to or smaller than 90°.

11. The magnetic sensor according to claim 1, wherein
the at least one magnetoresistive element includes a first surface that faces the non-facing part and a second surface opposite the first surface, and
a distance between at least a part of the non-facing part and the second surface is the same as a distance between the first surface and the second surface.

12. The magnetic sensor according to claim 1, further comprising:
two yokes disposed on both sides of the at least one magnetoresistive element in the second direction, each of the two yokes being made of a soft magnetic material, wherein
the antiferromagnetic layer is disposed on the at least one magnetoresistive element, the first ferromagnetic layer, the insulating layer, and the two yokes.

13. The magnetic sensor according to claim 1, further comprising:
a first port;
a second port;
a third port;
a first resistor section disposed between the first port and the second port in circuit configuration; and
a second resistor section disposed between the second port and the third port in circuit configuration, wherein
each of the first resistor section and the second resistor section includes the at least one magnetoresistive element, the first ferromagnetic layer, the insulating layer, and the antiferromagnetic layer,
the plurality of magnetic films include a free layer having a magnetization whose direction is variable depending on a target magnetic field,
in the first resistor section, the first ferromagnetic layer and the first antiferromagnetic portion constitute a first magnetic field generator that generates a first magnetic field to be applied to the at least one magnetoresistive element,
in the second resistor section, the first ferromagnetic layer and the first antiferromagnetic portion constitute a second magnetic field generator that generates a second magnetic field to be applied to the at least one magnetoresistive element,
the first magnetic field includes, as a main component, a component in a first magnetic field direction that is one direction parallel to the first direction,
the second magnetic field includes, as a main component, a component in a second magnetic field direction opposite to the first magnetic field direction,
in the first resistor section, the magnetization of the free layer includes a component in the first magnetic field direction in a case where the target magnetic field is not applied to the magnetic sensor, and
in the second resistor section, the magnetization of the free layer includes a component in the second magnetic field direction in a case where the target magnetic field is not applied to the magnetic sensor.
